(19) United States
(12) Patent Application Publication
(10) Pub. No.: US 2025/0357931 A1
(43) Pub. Date: Nov. 20, 2025

(54) High-Speed Compact Look-Up Table with Input Select and Registers

(71) Applicants: Zeno Semiconductor, Inc., Sunnyvale, CA (US); University of Southern California, Los Angeles, CA (US)

(72) Inventors: Young Hyun Cho, Chatsworth, CA (US); Yuniarto Widjaja, Cupertino, CA (US)

(21) Appl. No.: 18/866,501

(22) PCT Filed: May 16, 2023
(86) PCT No.: PCT/US2023/022295

§ 371 Date: Nov. 15, 2024

Related U.S. Application Data
(60) Provisional application No. 63/342,433, filed on May 16, 2022.

(51) Int. Cl. H03K 19/17728; H03K 3/037; H10B 12/00; H10B 41/30; H10B 43/30; H10B 61/00; H10B 63/10

(52) U.S. Cl. CPC H03K 19/17728; H03K 3/037; H10B 12/20; H10B 41/30; H10B 43/30; H10B 61/10; H10B 63/10

(57) ABSTRACT

Reconfigurable device components such as look up tables (LUT), D-flip flop registers and internal switch designs for programmable array of logic (PLA), programmable logic array (PLA), programmable logic device (PLD), complex PLD (CPLD), field programmable gate arrays (FPGAs), eASIC, structured ASIC, embedded FPGAs, and other programmable hardware devices are provided.

### TECHNICAL FIELD

This invention relates to reconfigurable hardware logic device and architecture.

### BACKGROUND OF THE INVENTION

Many computing devices are application specific integrated circuit (ASIC). ASICS are permanent layouts of integrated circuits and wires that perform specified functions with specific area, power, and speed characteristics. While non-recurring engineering (NRE) cost of designing ASIC tend to be high, per-chip cost can be very low for large volume applications. On the other hand, reconfigurable logic devices such as field programmable gate array (FPGA) provide reconfigurable hardware logic and wires that are designed to be configured after chip manufacturing process to provide a variety of custom hardware solutions. While reconfigurable devices provide flexible hardware platform and lower NRE cost (given that multiple custom hardware designs can be mapped onto the same device), these advantages come at a cost of larger die area, higher per-chip price, higher power consumption, and lower speed. These differences between ASIC and FPGA are well understood and considered by hardware developers when designing new chips.

Accordingly, a new reconfigurable hardware device and architecture that provides lower chip area and power than conventional reconfigurable circuits (such as FPGA) is desired to achieve computing devices with increased flexibility without power and area overhead with conventional FPGA.

### BRIEF SUMMARY OF THE INVENTION

A reconfigurable hardware logic device and architecture are disclosed, including for example a reconfigurable look-up table (LUT), D-Flip Flop or registers, and minimum footprint multiplexers used for, for example, internal switch design.

According to one aspect of the present invention, a look-up-table is provided that includes: a plurality of programmable memory cells; and a plurality of multiplexers connected in multiple stages to form a tree-like structure, wherein a first stage of the multiple stages is connected to the plurality of programmable memory cells and has a greatest number of the multiplexers of all of the multiple stages; wherein a last stage of the multiple stages has a least number of the multiplexers and is configured to forward a look-up table output that is a selected memory state of one of the plurality of memory cells; wherein the multiplexer comprises at least two transistors; and at least one inverter connected to an output of at least one of the multiplexers; and input select pins of the multiplexers configured to connect to input sources to provide input to the look-up-table.

In at least one embodiment, the look-up table includes a plurality of the inverters, wherein outputs of every stage of the multiple stages are connected to inputs of the inverters; and outputs of the inverters are connected to inputs of a subsequent stage of multiplexers, except for one of the inverters connected to the multiplexer in the last stage.

In at least one embodiment, inputs provided to the input select pins are all independent of one another.

In at least one embodiment, the look-up table further includes buffers between at least two of the stages of the multiple stages of multiplexers.

In at least one embodiment, the buffers include additional ones of the inverters.

In at least one embodiment, at least one of the plurality of programmable memory cells includes a static random access memory bit cell.

In at least one embodiment, at least one of the plurality of programmable memory cells includes a single transistor bi-stable static random access memory bit cell.

In at least one embodiment, at least one of the plurality of programmable memory cells includes a resistance change element.

In at least one embodiment, at least one of the plurality of programmable memory cells includes a single magneto-resistive random-access memory bit cell.

In at least one embodiment, at least one of the plurality of programmable memory cells includes a phase change material.

In at least one embodiment, at least one of the plurality of programmable memory cells includes a metal-oxide-metal system.

In at least one embodiment, at least one of the plurality of programmable memory cells includes a single dynamic random-access memory bit cell.

In at least one embodiment, the look-up table output is pre-charged to a predetermined state before forwarding the memory cell state.

In at least one embodiment, the look-up table further includes a transistor to set the look-up table output to the predetermined state.

In at least one embodiment, the look-up table output is configured to write the state of the programmable memory cells.

In at least one embodiment, the look-up table further includes a control circuitry to enable write to the programmable memory cells.

In at least one embodiment, the plurality of multiplexers include two-input to one-output multiplexers and the tree-like structure is a binary tree arrangement, the plurality of multiplexers being arranged and configured to forward one memory cell state; wherein each multiplexer includes one p-channel metal-oxide-semiconductor field-effect transistor and one n-channel metal oxide-semiconductor field-effect transistor; and wherein the look-up table includes look-up table input pins, each of the look-up-table input pins being connected to the select input signals of the multiplexers in each stage.

In at least one embodiment, each of the multiplexers includes one or more memory cells with state outputs that are used to multiplex two or more look-up-table inputs; each memory cell output is connected to a select input signal of a multiplexer in one of the levels of multiplexer tree.

In at least one embodiment, the multiplexers are two-input to one-output multiplexers, each multiplexer including one p-channel metal oxide-semiconductor field-effect transistor and one n-channel metal-oxide-semiconductor field-effect transistor; and wherein one memory cell state output is connected to the gate of the p-channel and n-channel transistors to forward one of two inputs.

According to another aspect of the present invention, a two-input to one-output programmable switch module includes: one p-channel metal-oxide-semiconductor field-effect transistor having a gate pin; and one n-channel metal-oxide semiconductor field-effect transistor connected to the gate pin; wherein the state of a programmable memory cell is connected to the gate pin; and the switch module is configured to select one of two inputs.

In at least one embodiment, each programmable memory cell is a static random access memory bit cell.

In at least one embodiment, each programmable memory cell is a single transistor bi-stable static random access memory bit cell.

In at least one embodiment, each programmable memory cell includes a resistance change element.

In at least one embodiment, each programmable memory cell is a single magneto-resistive random-access memory bit cell.

In at least one embodiment, each programmable memory cell includes a phase change material.

In at least one embodiment, each programmable memory cell includes a metal-oxide-metal system.

In at least one embodiment, each programmable memory cell is a single dynamic random-access memory bit cell.

According to another aspect of the present invention, an edge triggered D-flip flop includes: a D-flip flop input; first and second multiplexers that are cascaded one after another, the first multiplexer including multiple first inputs and a first output, the second multiplexer including multiple second inputs and a second output; wherein the D-flip flop input is connected to one of the first inputs, the first output is fed back to another of the first inputs and the first output is also connected to one of the second inputs; and wherein the second output is fed back to another of the second inputs, the second output is an output of the D-flip flop.

According to another aspect of the present invention, an edge triggered D-flip flop includes: a D-flip flop input and a D-flip flop output; first and second multiplexers that are cascaded one after another, the first multiplexer including multiple first inputs and a first output, the second multiplexer including multiple second inputs and a second output; first and second capacitors; a first inverter having a first inverter input and a first inverter output; and a second inverter having a second inverter input and a second inverter output; wherein said D-flip flop input is connected to one of the first inputs, the first output is fed back to another of the first inputs and the first output is also connected to the first capacitor and the first inverter input; wherein the first inverter output is connected to one of the second inputs, the second output is fed back to another of the second inputs and the second output is also connected to the second capacitor and the second inverter input; and wherein the second output is also connected to the D-flip flop output.

According to another aspect of the present invention, a level triggered D-flip flop includes: a first 2-input look-up table having two first inputs and a first output; a second 2-input look-up table having two second inputs and a second output; a third 2-input look-up table having two third inputs and a third output; a fourth 2-input look-up table having two fourth inputs and a fourth output; a D-flip flop input connected to one of the first inputs and one of the second inputs; a clock input connected to another of the first inputs and another of the second inputs; the first output connected to one of the third inputs; the second output connected to one of the fourth inputs; the third output connected to another of the fourth inputs and a first output of the level triggered D-flip flop; and the fourth output connected to another of the third inputs and a second output of the level triggered D-flip flop.

According to another aspect of the present invention, a level triggered D-flip flop includes: a first look-up-table having three or more first inputs and a first output; a second look-up table having three or more second inputs and a second output; a D-flip flop input connected to one of the first inputs and one of the second inputs; a clock input connected to another of the first inputs and another of the second inputs; the first output connected to still another of the second inputs and a first output of the level triggered D-flip flop; and the second output connected to still another of the first inputs and a second output of the level triggered D-flip flop.

According to another aspect of the present invention, an edge triggered D-flip flop includes: a first look-up-table based level triggered D-flip flop module having at least two first inputs and a first output; a second look-up-table based level triggered D-flip flop module having at least two second inputs and a second output; a D-flip flop input connected to one of the first inputs; a clock input connected to another of the first inputs and one of the second inputs; the first output connected to another of the second inputs; and the second output being an output of the edge triggered D-flip flop.

According to another aspect of the present invention, an edge triggered D-flip flop includes: a first look-up-table with three or more first inputs and a first output; a second look-up table with three or more second inputs and a second output, the first and second look-up tables being connected to enable D-flip-flop function; a D-flip flop input connected to one of the first inputs; a D-flip flop triggering input connected to another of the first inputs and one of the second inputs; the first output being fed back to still another of the first inputs and inputted to another of the second inputs; and the second output being fed back to still another of the second inputs and outputted as a D-flip flop output.

These and other aspect and advantages of the present invention will be provided in the detailed description that follows.

### BRIEF DESCRIPTION OF THE DRAWINGS

FIG. 1 illustrates an example of a logic block comprising reconfigurable gates, D-flip flop or register, and multiplexer.

FIG. 2 is a schematic illustration of a reconfigurable look-up table.

FIG. 3 is a schematic illustration of a 2-to-1 multiplexer according to an embodiment of the present invention.

FIGS. 4 is a schematic illustration of a 2-input look-up table according to an embodiment of the present invention.

FIG. 5A is a schematic illustration of a 2-input look-up table according to an embodiment of the present invention.

FIG. 5B is a schematic illustration of a 2-input look-up table according to an embodiment of the present invention.

FIG. 5C is a schematic illustration of a 2-input look-up table according to an embodiment of the present invention.

FIG. 5D is a schematic illustration of a 2-input look-up table according to an embodiment of the present invention.

FIG. 6 is a schematic illustration of a 2-input look-up table according to an embodiment of the present invention.

FIG. 7 is a schematic illustration of an m-input look-up table according to an embodiment of the present invention.

FIG. 8A is a schematic illustration of a switch box comprising a reconfigurable 2-to-1 multiplexer according to an embodiment of the present invention.

FIG. 8B is a schematic illustration of a switch box comprising a reconfigurable 2-to-1 multiplexer according to an embodiment of the present invention.

FIG. 9 illustrates a memory component connected to a control circuitry, according to an embodiment of the present invention.

FIG. 10 is a schematic illustration of an edge-triggered D-Flip Flop configured using multiplexers according to embodiments of the present invention.

FIG. 11A is a schematic illustration of an edge-triggered D-Flip Flop configured using multiplexers according to an embodiment of the present invention.

FIG. 11B is a schematic illustration of an edge-triggered D-Flip Flop configured using multiplexers according to an embodiment of the present invention.

FIG. 12 is a schematic illustration of a level-triggered D-Flip Flop configured using reconfigurable look-up tables according to an embodiment of the present invention.

FIG. 13 is an exemplary configuration of the look-up table shown in FIG. 12.

FIG. 14 is a schematic illustration of a level-triggered D-Flip Flop configured using reconfigurable look-up tables according to an embodiment of the present invention.

FIG. 15 is an exemplary configuration of the look-up tables shown in FIG. 14.

FIG. 16 is a schematic illustration of an edge-triggered D-Flip Flop configured using level-triggered D-Flip Flops according to an embodiment of the present invention.

FIG. 17 is a schematic illustration of an edge-triggered D-Flip Flop configured using level-triggered D-Flip Flops according to an embodiment of the present invention.

FIG. 18 is a schematic illustration of an edge-triggered D-Flip Flop configured using 3-input look-up tables (LUT3s) according to an embodiment of the present invention.

FIG. 19 illustrates an example of a programmable logic unit according to an embodiment of the present invention.

FIG. 20 illustrates a programmable logic unit according to another embodiment of the present invention.

FIG. 21 illustrates a programmable logic unit according to another embodiment of the present invention.

FIG. 22 illustrates a programmable logic unit according to another embodiment of the present invention.

FIG. 23 illustrates a programmable logic unit according to another embodiment of the present invention.

FIG. 24 illustrates a programmable logic unit according to another embodiment of the present invention.

FIG. 25 illustrates a 4-input look-up table according to an embodiment of the present invention.

FIGS. 26A-26D illustrate non-limiting examples of sources from which inputs 80a-80d can be generated for the embodiment of FIG. 25.

FIG. 27 is a schematic illustration of one non-limiting example of an SRAM memory cell (single transistor bi-stable static random access memory bit cell) that can be used for a memory component according to an embodiment of the present invention.

FIG. 28A schematically illustrates one non-limiting example of a resistance change element that may be used in an embodiment of the present invention.

FIG. 28B shows a resistance change element represented as a variable resistor that can be used in an embodiment of the present invention.

FIG. 29 is a schematic illustration of one non-limiting example of a single magneto-resistive random-access memory (MRAM) bit cell that can be used in an embodiment of the present invention.

FIG. 30A is a schematic illustration of one non-limiting example of a single dynamic random-access memory bit cell that can be used in an embodiment of the present invention.

FIG. 30B illustrates another example of a single dynamic random-access memory bit cell that can be used in an embodiment of the present invention.

FIG. 31 shows an example of a memory cell having both volatile and non-volatile functionality that can be used in an embodiment of the present invention.

FIG. 32 shows a memory cell having both volatile and non-volatile functionality that can be used in an embodiment of the present invention, where a resistive change memory element is used to store non-volatile memory data.

### DETAILED DESCRIPTION OF THE INVENTION

Before the present devices are described, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “an”, and “the” include plural referents unless the context clearly dictates otherwise. Thus, for example, reference to “a table” includes a plurality of such tables and reference to “the input” includes reference to one or more inputs and equivalents thereof known to those skilled in the art, and so forth.

The publications discussed herein are provided solely for their disclosure prior to the filing date of the present application. The dates of publication provided may be different from the actual publication dates which may need to be independently confirmed.

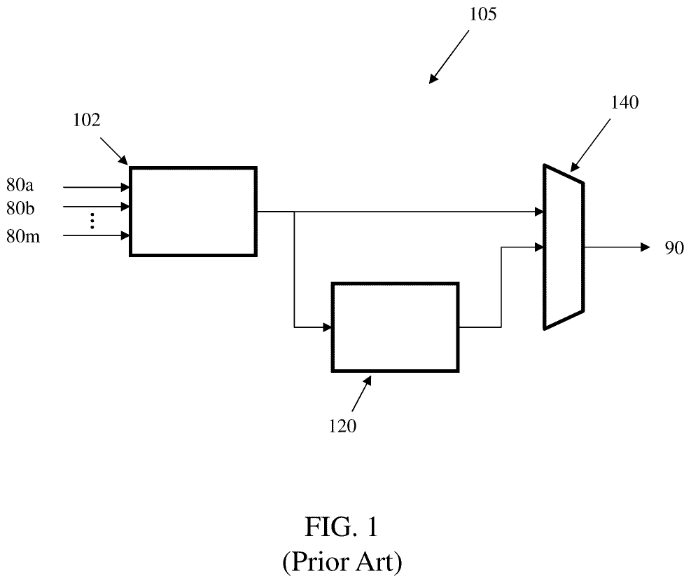

The reconfigurable fabric of a conventional FPGA generally consists of an array of logic blocks and switch boxes that interconnect them. FIG. 1 illustrates an example of a reconfigurable logic block 105 comprising reconfigurable gates (which may be implemented using look-up tables) 102, D-flip flop or register 120, multiplexer 140, and other discrete components (not shown) that enable multiple hardware configurations that are useful. Conventional reconfigurable gates are usually made of an array of 1-bit memory components followed by a decoder which gives output of the gate. This implementation of reconfigurable gates 102 is often referred to as a look-up table (LUT).

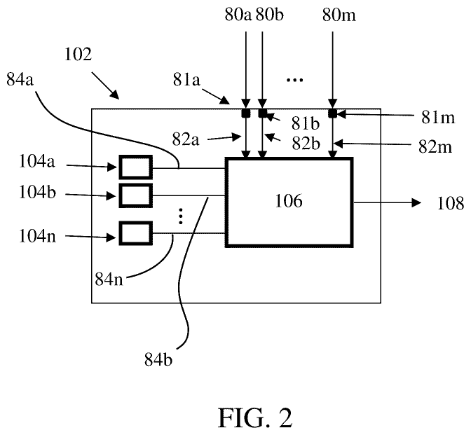

FIG. 2 illustrates an example of a generic LUT 102, comprising an array of memory components 104a-104n, and decoder 106, where the input signals are 80a-80m and the output of the LUT is signal 108. The input signals 80a-80m are connected to the input pins 81a-81m, which then become the input select signals 82a-82m of the decoder 106. The size and power of the reconfigurable gate design is dependent on the number of input pins 81a-81m of the gate 102 (which could be implemented as LUT), and usually double with each additional pin. Furthermore, the latency through the gate also increases with additional pins due to the added level(s) of decoders needed to multiplex the output of memory components 104a-104n. Memory components 104a-104n may be made of, for example, 6-transistor static random-access memory (SRAM), 1-transistor/1-capacitor dynamic random-access memory (DRAM), resistance change elements, magneto-resistive elements, electric fuse (eFuse), antifuse, direct electric connections, 1-transistor SRAM utilizing the properties of intrinsic vertical bipolar transistors (for example as described in U.S. Pat. No. 8,130,548 to Widjaja et al., titled “Semiconductor Memory Having Floating Body Transistor and Method of Operating” (“Widjaja-1”), U.S. Pat. No. 8,077,536, “Method of Operating Semiconductor Memory Device with Floating Body Transistor Using Silicon Controlled Rectifier Principle” (“Widjaja-2”), U.S. Pat. No. 9,230,651, “Memory Device Having Electrically Floating Body Transistor” (“Widjaja-3”), all of which are hereby incorporated herein, in their entireties, by reference thereto), and/or other memory elements.

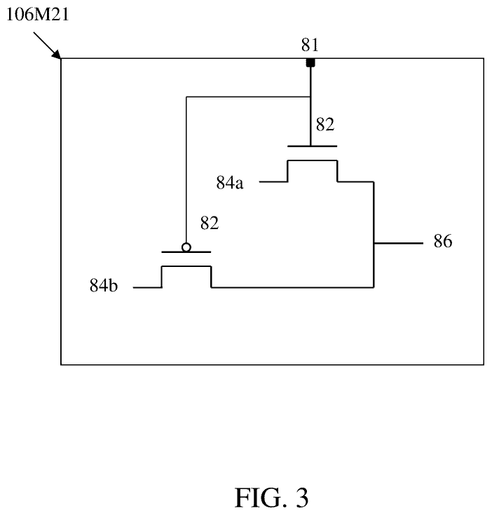

FIG. 3 illustrates an exemplary embodiment of a 2-to-1 multiplexer (MUX) 106M21 according to an embodiment of the present invention. The signal from the input pin 81 becomes the input select signal 82 of the 2-to-1 MUX. Based on the input select signal 82, the 2-to-1 MUX selects and forwards one of the input signals 84a (from memory component 104a) and 84b (from memory component 104b) to the output node 86. The 2-to-1 MUX comprises one p-channel metal-oxide-semiconductor field-effect transistor (MOSFET) and one n-channel MOSFET. From here on, the input signals 80 of the gates and the input select signals 82 of the MUX may be used interchangeably and the input pins 81 of the MUX may not be shown in the drawings.

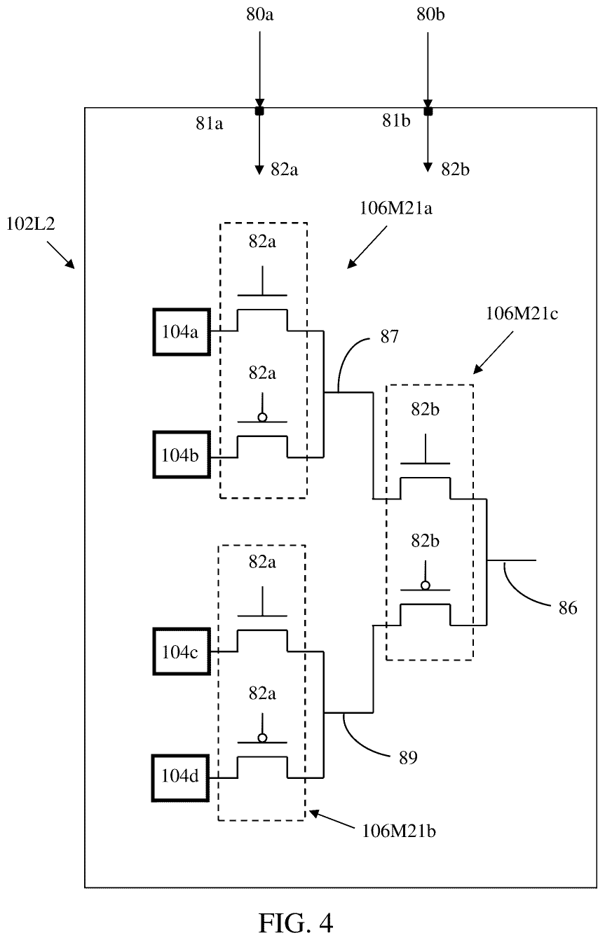

In one embodiment of the present invention, 2-to-1 MUX 106M21 can be connected in multiple stages to form a tree-like structure to forward one of many memory states of many memory cells 104, respectively, provided as look-up table inputs, for example as illustrated in 2-input look table (LUT2) 102L2 shown in FIG. 4. LUT2 102L2 comprises four memory components 104a, 104b, 104c and 104d, and three 2-to-1 MUX 106M21a, 106M21b, and 106M21c. The input signals 80a and 80b of the LUT2 102L2 are connected to pins 81a and 81b, which then become the input select signals 82a and 82b of the MUX 106M21a and MUX 106M21b. For simplicity, the connections between input select signals 82a and 82b from the pins 81a and 81b to the gates of the transistors inside the MUX 106M21a and MUX 106M21b are not shown. However, the signals with the same labels are understood to be the same. MUX 106M21a and MUX 106M21b are arranged in a first stage of a tree structure and MUX 106M21c is arranged in a second stage of the tree structure. Based on the input signal 80a provided to input pin 81a, which then becomes the input select signal 82a of 106M21a and 106M21b in the first stage and input signal 80b provided to input pin 81b, which then becomes the input select signal 82b of 106M21c in the second stage, and the states or data stored in the memory elements, 104a-104d, LUT2 102L2 generates an output signal 86 by selecting the appropriate memory state or data of the memory element 104a, 104b, 104c, or 104d that is dictated by the application of the input select signals 82a and 82b as described. At the first stage in this embodiment, application of input select signal 82a to 106M21a as described is used to determine whether to select the state of 104a or 104b as output 87, and application of input select signal 82a to 106M21b as described is used to determine whether to select the state of 104c or 104d as output 89. At the second stage, application of input select signal 82b to 106M21c as described is used to determine whether to select the output 87 or the output 89 (both having been inputted to 106M21c) as output 86.

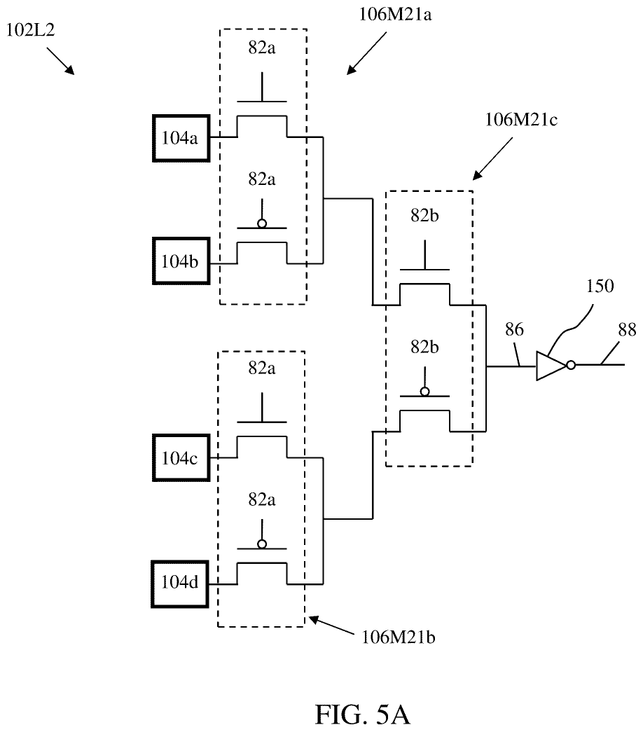

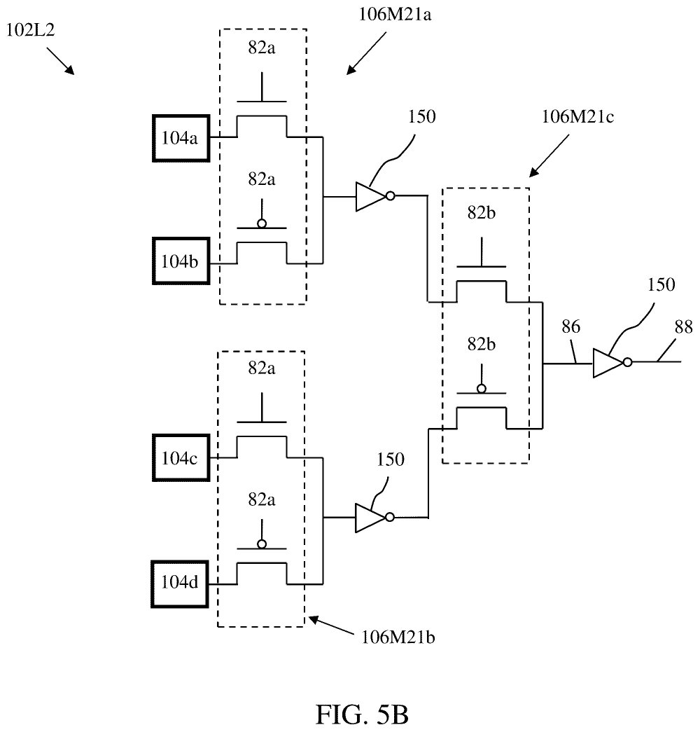

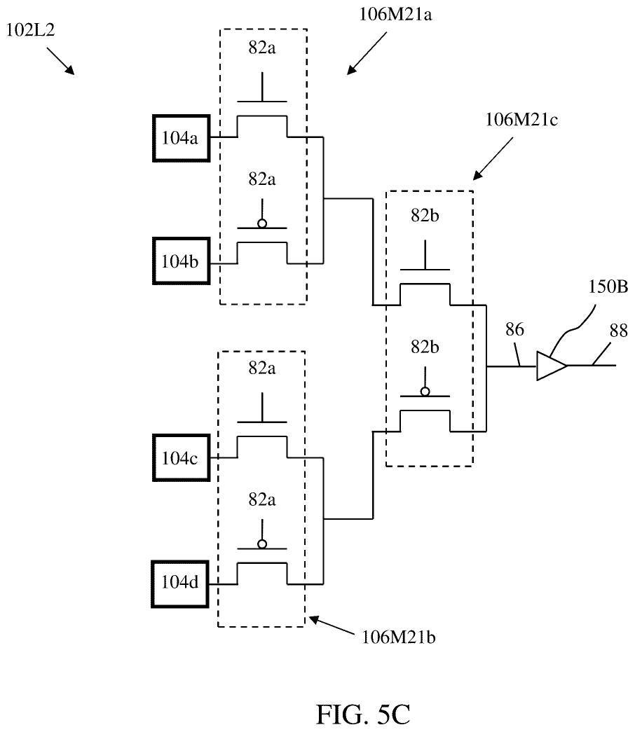

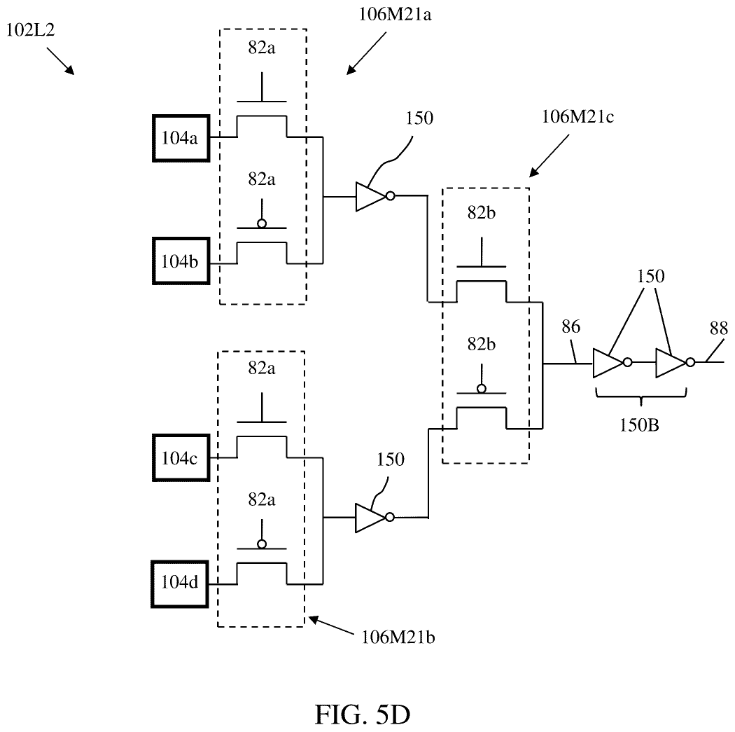

LUT2 102L2 may optionally include an inverter 150 to generate output signal 88, as illustrated in FIG. 5A. Further optionally, inverters 150 may be connected between more than one MUX stage, up to and including between all stages, as well as to the output of the last stage. FIG. 5B shows an embodiment in which inverters 150 are connected to outputs of the first stage of MUXs (106M21a and 106M21b) with the outputs of these inverters being connected to the inputs of the second stage MUX 106M21c. The inverters 150 may be used to restore potential drops across the MUX stages. In the embodiment of FIG. 5A, the inverter 150 connected to the output of the second stage of MUXs (106M21c) results in a logically inverted output signal 88. In the embodiment of FIG. 5B, inverters 150 connected to outputs of the first stage of MUXs (106M21a and 106M21b) and inverter 150 connected to the output of the second stage of MUXs (106M21c) result in a logically non-inverted output 88. If an odd number of stages of inverters are inserted between inputs and output of the LUT, the final output will be logically inverted, such as in FIG. 5A for example. This inverted output of decoder can be compensated by logically inverting the state of memory components of that look-up-table. However, when the number of stages of inverters 150 is even (such as the two stages of inverters 150 shown in FIG. 5B), the final output will not be inverted.

LUT2 102L2 may also include one or more buffers 150B in between stages of the MUXs, and/or to generate the output signal 88. FIG. 5C illustrates an example in which buffer 150B is located after the stage having MUX 106M21c, where it is used in generating output signal 88. Further alternatively or additionally, buffer(s) 150B may be used to restore potential drops across one or more MUX stages. Optionally, buffer 150B may be implemented using two inverters 150 as illustrated in FIG. 5D.

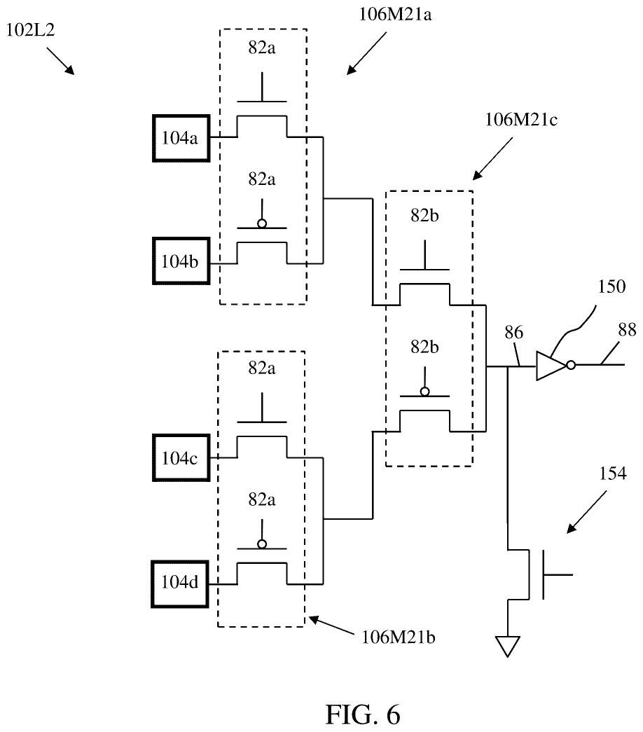

The output signal of LUT 102L2 (as well as other embodiments) may optionally be pre-charged to a predetermined level. FIG. 6 shows an exemplary embodiment of the present invention showing a pre-charge transistor 154 to first pre-charge node 86 to about 0V and correspondingly the output node 88 to high potential about the supply voltage VDD level.

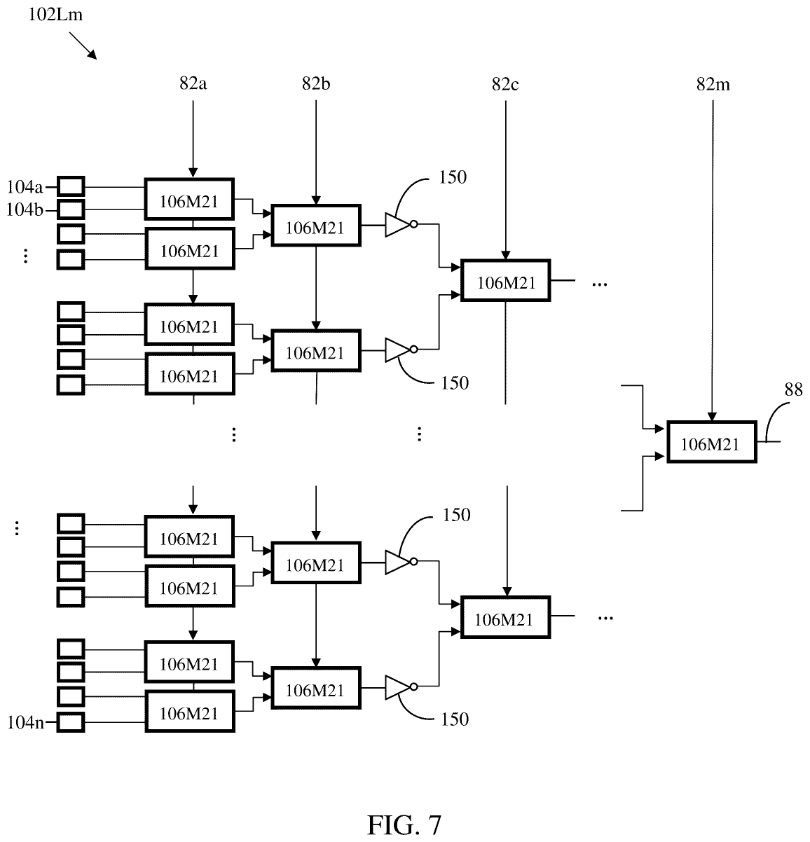

In the embodiments shown in FIGS. 4-6, the inputs 80a, 80b to the LUT2 102L2 connected as select signals 82a, 82b of the MUX 106M21a (106M21b) and 106M21c are independent, i.e., no input signals are generated as inverted values of other input signals, in contrast to some prior art devices which send some inputs as inverted signals of other inputs to drive NMOS and PMOS. The LUT2 102L2 architecture illustrated in FIGS. 4-6 can be scaled to an m-input LUT table, as schematically illustrated in FIG. 2. An exemplary implementation of m-input LUTm 102Lm is illustrated in FIG. 7. This embodiment comprises “n” memory components 104a, 104b, . . . 104n, where “n” is a positive integer that is an exponential value of 2 (i.e., 2^{m}), such as 2, 4, 8, 16, etc. LUTm 102Lm further includes “m” stages of MUX 106M21 to form the tree-like structure shown in FIG. 7, with m stages of MUX 106M21, where a first stage of MUX has n/2 number of MUX 106M21 and each successive stage has half that number, where the final stage m has only one MUX 106M21, for a total of n−1 of 2^{m-}1 MUX 106M21. Based on the input select signals 82a-82m (which originate from input signals 80a-80m (not shown)), LUTm 102Lm will generate an output signal 88 based on the states or data stored in the memory elements 104a-104n. In other embodiments of the present invention, as with previous embodiments, LUTm 102Lm may also comprise additional inverters between stages of MUX in addition to those shown between stages b and c in FIG. 7.

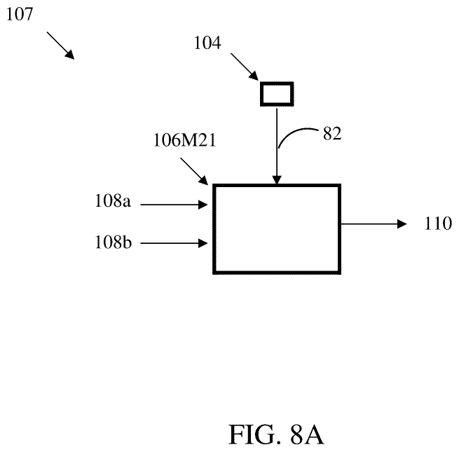

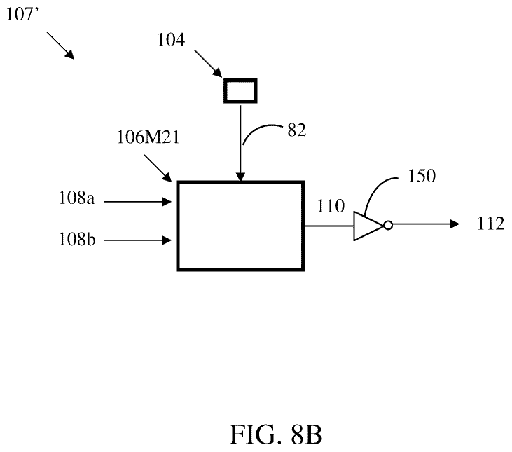

Multiplexers may be used to form programmable switch boxes. The role of switch boxes is to provide flexible interconnections between other components of the reconfigurable fabric. FIG. 8A illustrates a switch box 107 comprising a MUX, for example 2-to-1 MUX 106M21. The input select signal 82 to the multiplexers may be generated from other circuitry, or a memory element 104 may be used. When using a memory element 104, the state stored by the memory element 104 is used as the bit/input select signal 82 inputted to the multiplexer 106M21, causes it to forward one of the input signals 108a or 108b to the output terminal 110 based on the value of the select bit/input select signal 82 received by the multiplexer 106M21. Likewise, when other circuity is used, the other circuity provide the bit/input select signal 82, and the bit/input select signal 82 inputted to the multiplexer 106M21, causes the multiplexer 106M21 to forward one of the input signals 108a or 108b to the output terminal 110 based on the value of the select bit/input signal 82 received by the multiplexer 106M21. An inverter 150 may optionally be added to generate the inverted output signal 112 of switch box 107′ as illustrated in FIG. 8B.

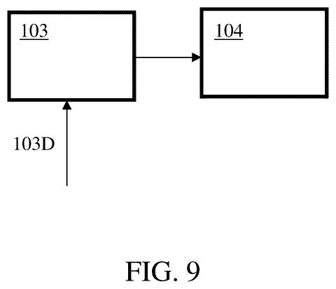

As illustrated in FIG. 9, each of the memory components 104 may be connected to a control circuitry 103, which writes the state or data stored in the memory component 104. The data to be stored in the memory component 104 is provided as input signal 103D. Input signal 103D may originate from external storage or embedded non-volatile memory in the reconfigurable logic chip or may also originate from the output of other reconfigurable logic fabric, such as other look-up tables.

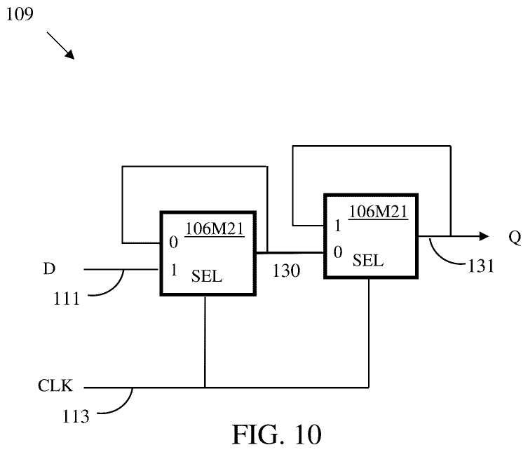

The multiplexer architecture illustrated for example in FIG. 3 can also be used to design a compact D-Flip Flop according to an embodiment of the present invention. FIG. 10 illustrates an edge triggered D-Flip Flop 109 comprising two multiplexers 106M21 that are cascaded one after another. The input D (111) of the D-Flip Flop 109 is connected to one of the inputs of the first multiplexer 106M21. The output 130 of the first multiplexer 106M21 is fed back to the second input of the same multiplexer 106M21. The output of the first multiplexer 106M21 is also connected to one of the inputs of the second multiplexer 106M21. The output 131 of the second multiplexer 106M21 is fed back to the second input of the second multiplexer 106M21. The multiplexer output of the second multiplexer 106M21 is the output of the D-Flip Flop 109, indicated as Q (131) in FIG. 10.

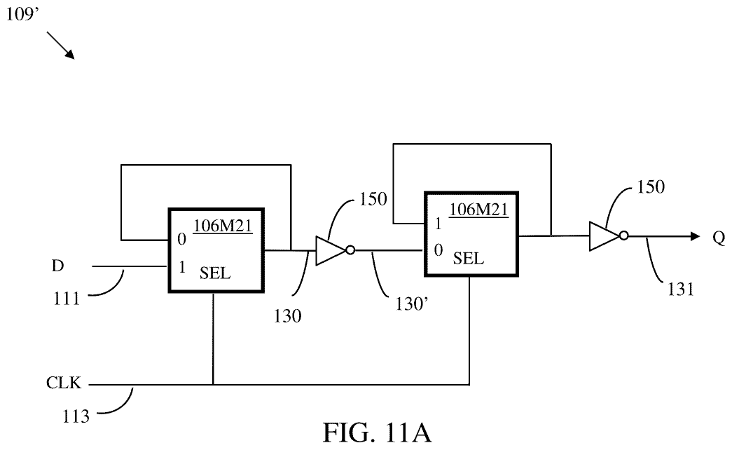

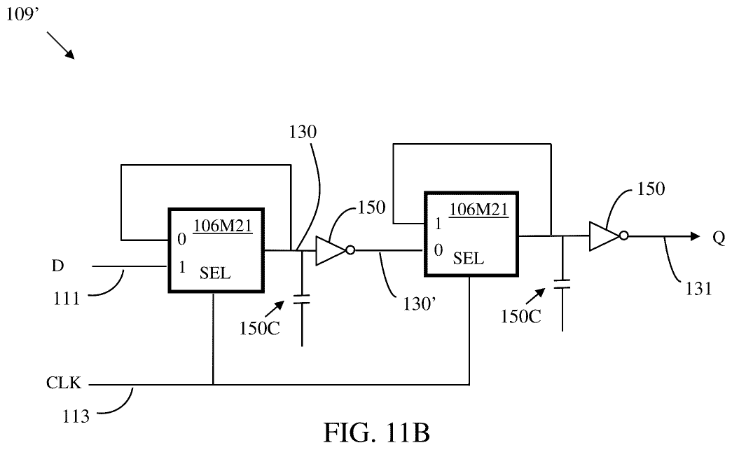

The input signal D (111) will first be propagated to node 130 when CLK signal 113 is high. At this time, the output signal Q (131) will be maintained at its previous state. When CLK signal 113 goes to low, the 106M21 will forward the potential of node 130 (which stores the input signal D) to the output Q (131). Inverters may optionally be added to the outputs of the multiplexers to restore or increase the drive of the D-Flip Flop. FIG. 11A illustrates an exemplary embodiment of D-Flip Flop 109′ comprising inverters 150 being connected to the outputs of the multiplexers 106M21, wherein output 130′ is the inverted value of output 130 in FIG. 10. The outputs of the multiplexers 1062M21 may optionally be connected to capacitors 150C, as illustrated in FIG. 11B.

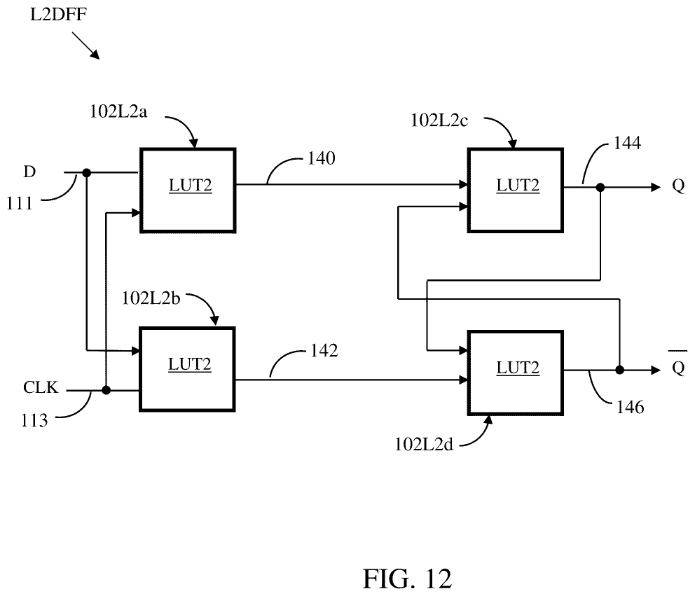

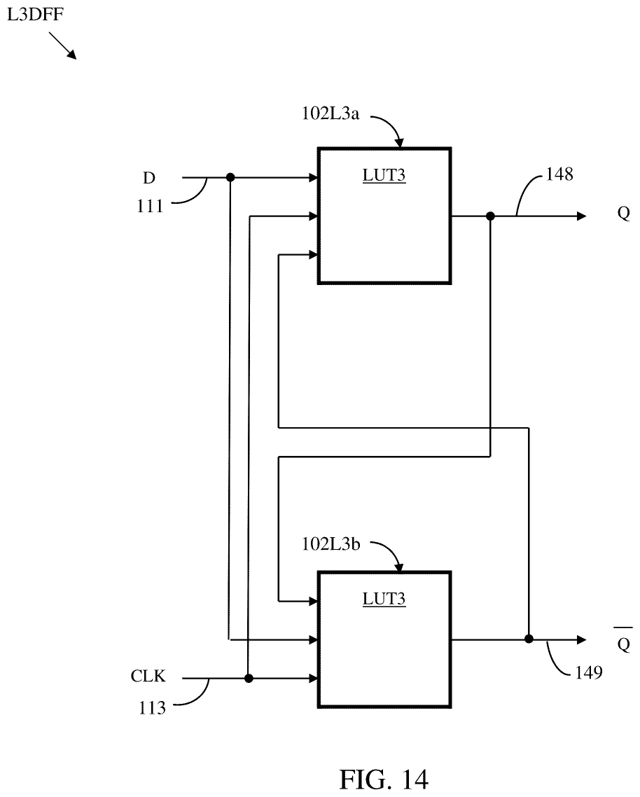

D-Flip Flop function may also be provided using multiple look-up tables. Examples of level and edge-triggered D-Flip Flops are described in FIGS. 12 and 14.

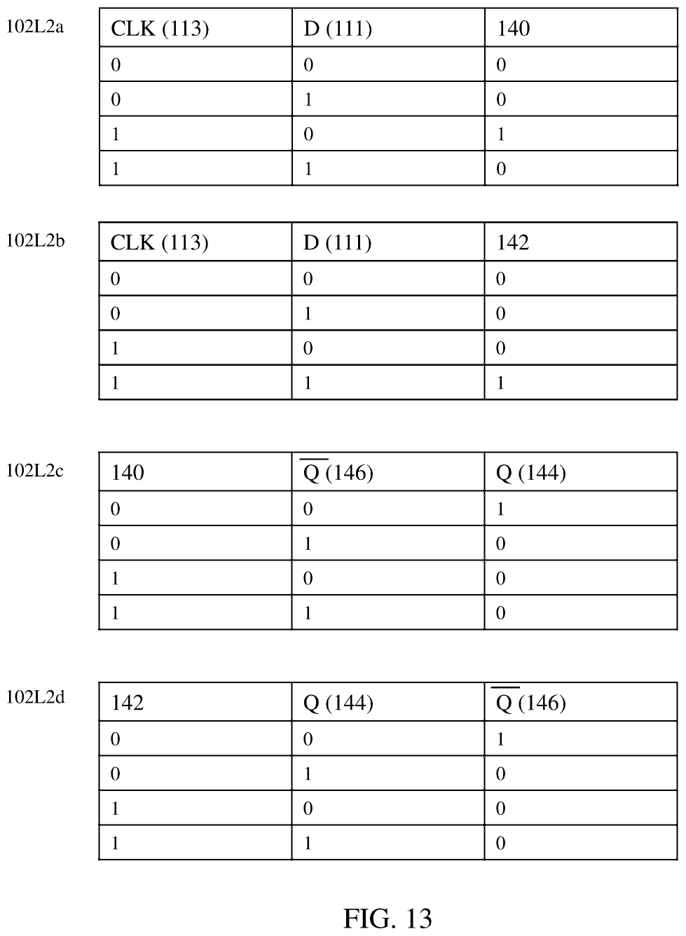

FIG. 12 shows an embodiment, according to the present invention, of a level triggered D-Flip Flop L2DFF. L2DFF in FIG. 12 is designed with four 2-input look-up-tables (LUT2) that are connected to enable D-Flip Flop function. Input D (111) of L2DFF and clock signal CLK 113 are connected to the first stage of 2-input look-up-tables (LUT2) 102L2a and 102L2b, respectively. The outputs 140 and 142 of the 2-input look-up-tables (LUT2) 102L2a and 102L2b in the first stage are connected to two 2-input look-up-tables (LUT2) 102L2c and 102L2d, respectively, in the second stage. The outputs 144, 146 of the two 2-input look-up-tables (LUT2) 102L2c, 102L2d in the second stage are forwarded to the inputs of the opposing 2-input look-up-table (LUT2) 101Ld, 102Lc in the second stage. FIG. 13 illustrates an example of how the LUT2 102L2a-d may be configured to create a D-Flip Flop L2DFF. As previously described, for example in FIGS. 4-6, each of the LUT2 102L2a-d comprises memory elements 104 to store the configuration of the LUT2 102L2a-d. For simplicity, the memory elements 104 are not shown in FIG. 12 and subsequent illustrations of LUTs.

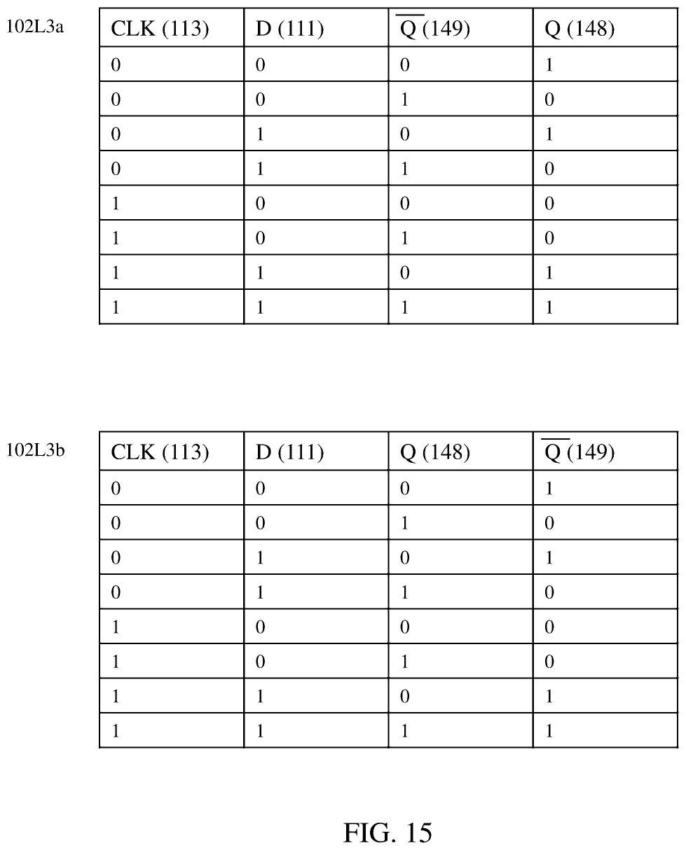

FIG. 14 shows a level triggered D-Flip Flop L3DFF comprising two look-up-tables (LUT3) 102L3a, 102L3b with three or more inputs each that are connected to enable D-Flip Flop function according to another embodiment of the present invention. The input signal D (111) and clock signal CLK (113) of D-Flip Flop L3DFF are each connected to both look-up-tables 102L3a and 102L3b. The outputs 148, 149 of the two look-up-tables 102L3a, 102L3b are forwarded to the inputs of the opposing look-up-tables. FIG. 15 illustrates an example of how the LUT3 102L3a and 102L3b may be configured to create a D-Flip Flop L3DFF according to an embodiment as shown in FIG. 14.

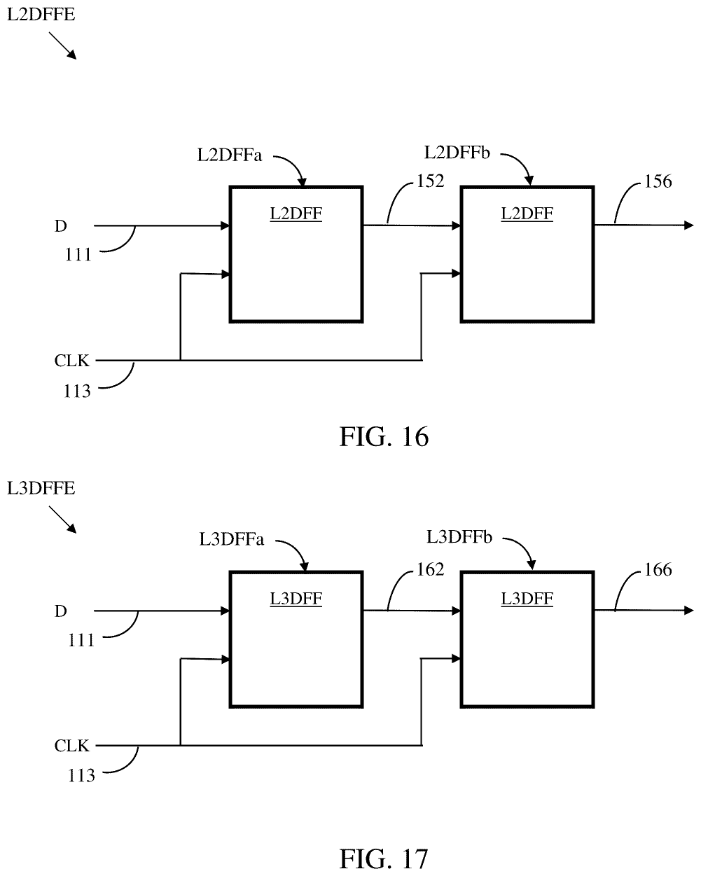

FIG. 16 illustrates an edge triggered D-Flip Flop L2DFFE according to an embodiment of the present invention. The input signal D (111) is connected as input to the first look-up table L2DFFa and clock signal CLK (113) is connected to both look-up tables L2DFFa and L2DFFb. The output 152 of L2DFFa is inputted to L2DFFb and the output 156 from L2DFFb is the output of L2DFFE.

In an edge-triggered D-Flip Flop, the output only changes during the CLK transition. The edge triggered D-Flip Flop L2DFFE may be configured to change the output when the CLK signal 113 is rising or when the CLK signal 113 is falling. The edge triggered D-Flip Flop L2DFFE comprises a look-up-table based level triggered D-flip flop module L2DFFa cascaded with a second look-up-table based level triggered D-flip flop module L2DFFb where the output 152 of the first module L2DFFa is connected as an input to the second module L2DFFb. The look-up-table based level triggered D-Flip Flop L2DFFa can be configured for the output 152 to change when the CLK signal 113 is high and the L2DFFb can be configured for the output 156 to change when the CLK 113 signal is low, or vice versa. As a result, the output of the L2DFFE will only change at the rising (or positive) edge of the CLK signal 113 or falling (or negative) edge of the CLK signal 113.

FIG. 17 illustrates an edge-triggered D-Flip Flop L3DFFE according to another embodiment of the present invention. The L3DFFE in this embodiment includes two LUT3-based level triggered D-flip flops L3DFFa and L3DFFb. The input signal D (111) is connected as input to the first LUT3-based level triggered D-Flip Flop L3DFFa and clock signal CLK (113) is connected to both LUT3-based level triggered D-Flip Flops L3DFFa and L3DFFb. The output 162 of L3DFFa is inputted to L3DFFb and the output 166 from L3DFFb is the output of L3DFFE.

The edge triggered D-Flip Flop L3DFFE may be configured to change the output when the CLK signal 113 is rising or when the CLK signal 113 is falling. The edge triggered D-Flip Flop L3DFFE comprises a look-up-table based level triggered D-flip flop module L3DFFa cascaded with a second look-up-table based level triggered D-flip flop module L3DFFb where the output 162 of the first module L3DFFa is connected as an input to the second module L3DFFb. The look-up-table based level triggered D-Flip Flop L3DFFa can be configured for the output 162 to change when the CLK signal 113 is high and the L3DFFb can be configured for the output 166 to change when the CLK signal 113 is low, or vice versa. As a result, the output of the L3DFFE will only change at the rising (or positive) edge of the CLK signal 113 or falling (or negative) edge of the CLK signal 113.

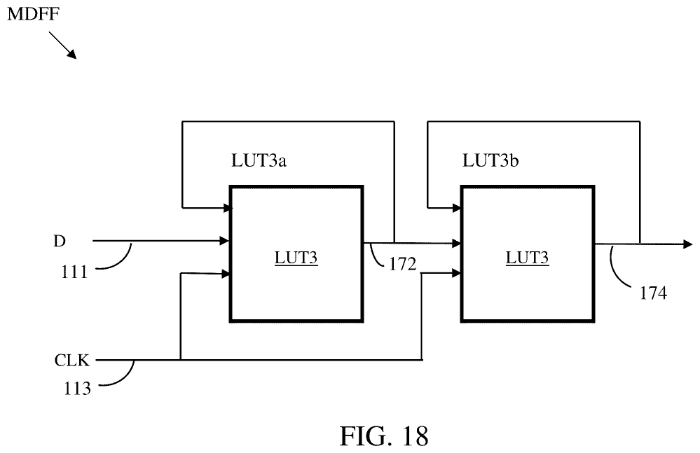

FIG. 18 illustrates an edge-triggered D-Flip Flop MDFF (multiplexer-based D-Flip Flop) according to another embodiment of the present invention. Edge-triggered D-Flip Flop MDFF comprises two look-up tables LUT3a, LUT3b each having three (or more) inputs. The MDFF D-flip flop input D (111) is connected to one of the inputs of the first look-up-table LUT3a. A D-flip flop triggering input (i.e., clock signal CLK (113)) is connected to another input of the first look-up-table LUT3a and one of the inputs of the second look-up-table LUT3b. The output 172 of the first look-up-table LUT3a is fed back to a third input of the first look-up-table LUT3a. The output 172 is also connected to one of the inputs of the second look-up-table LUT3b. The output 174 of the second look-up-table LUT3b is fed back to a third input of the second look-up-table LUT3b. The output 174 is also the output of the D-flip flop MDFF.

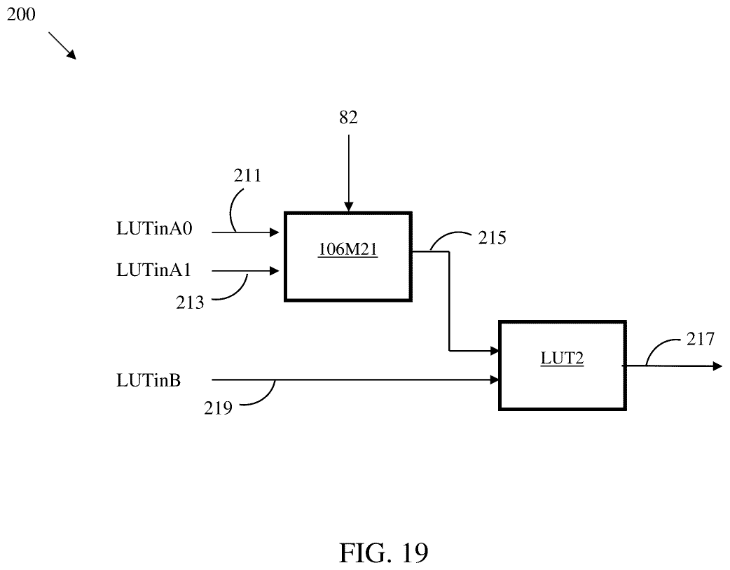

Some of the programmable logic fabric (components, elements or units of reconfigurable logic) above may be combined to create other programmable logic units. FIG. 19 illustrates an example of a programmable logic unit 200 according to an embodiment of the present invention, where a 2-to-1 MUX 106M21 is used to select one of the inputs LUTinA0 (211) and LUTinA1 (213) based in the input select signal 82 received by 106M21. The output 215 of 106M21 is connected to the input of a 2-input look-up table LUT2, where the output 217 is selected from the output 215 (which can also be referred to as LUTinA) of the 106M21 and the input LUTinB (219).

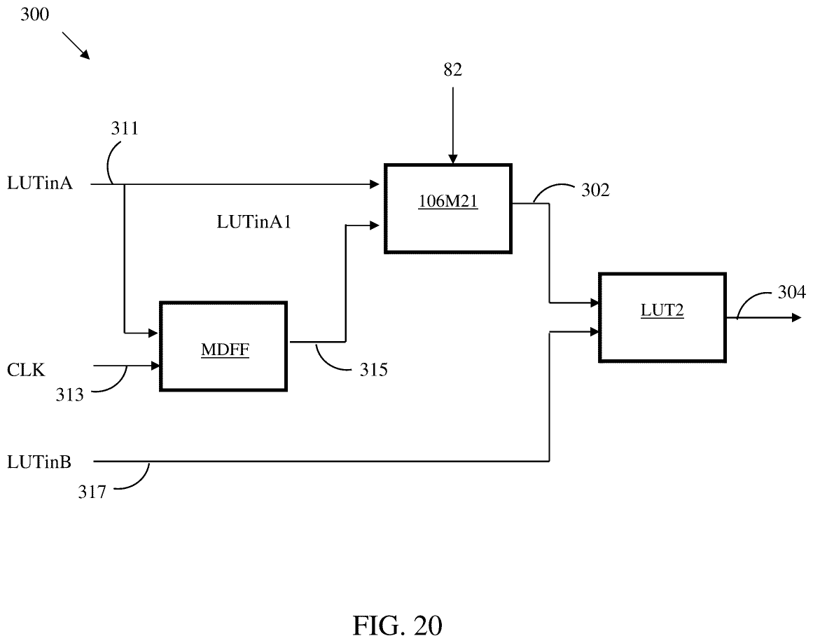

FIG. 20 illustrates a programmable logic unit 300 according to another embodiment of the present invention. In this embodiment, an input signal LUTinA (311) is inputted to an edge-triggered D-Flip Flop MDFF, as well as a 2-to-1 MUX 106M21. A clock signal 313 is also inputted to MDFF. The output 315 from MDFF is inputted to 106M21. The output 302 from 106M21 is selected from 311 and 315 based on the input select signal 82 to the MUX 106M21 and is a first input to look-up table LUT2. Input signal LUTinB (317) is a second input to look-up table LUT2. The output 304 of the programmable logic unit 300 is the output from LUT2 which is selected from the output 302 of 106M21 and LUTinB (317).

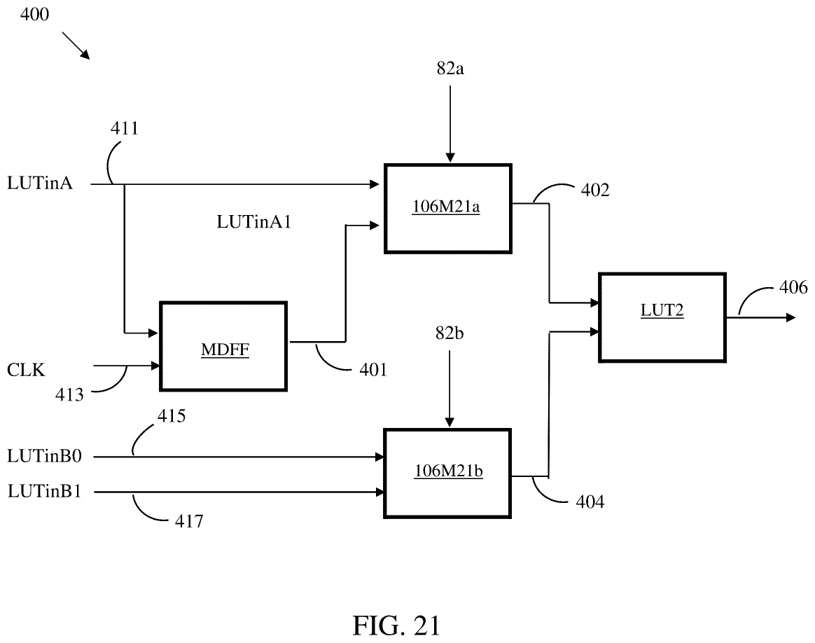

FIG. 21 illustrates a programmable logic unit 400 according to another embodiment of the present invention. Programmable logic unit 400 comprises an edge-triggered D-Flip Flop MDFF, two 2-to-1 MUX 106M21 (106M21a and 106M21b with corresponding input select signals 82a and 82b), and a 2-input look-up table LUT2. In this embodiment, an input signal LUTinA (411) is inputted to an edge-triggered D-Flip Flop MDFF, as well as a 2-to-1 MUX 106M21a. A clock signal CLK (413) is also inputted to MDFF. The output 401 from MDFF is inputted to 106M21a. The output 402 from 106M21a is a first input to look-up table LUT2. Second and third inputs LUTinB0 (415) and LUTinB1 (417) are inputs to a second 2-to-1 MUX 106M21b. The output 404 from MUX 106M21b is a second input to LUT2. The output 406 of the programmable logic unit 400 is the output from LUT2 which is selected from the output of the 106M21a and the output of 106M21b.

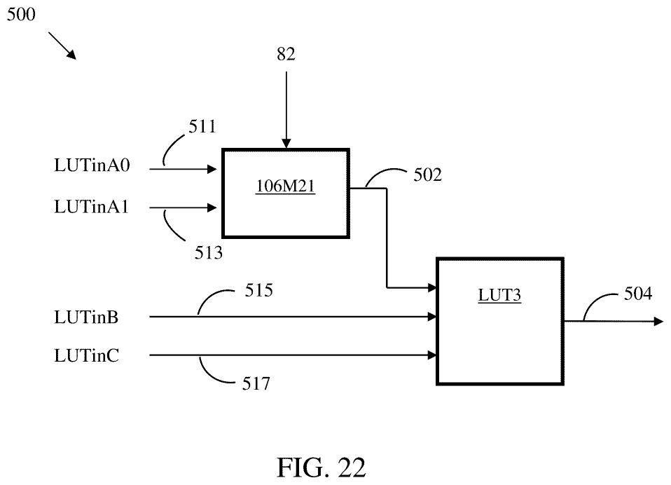

FIG. 22 illustrates a programmable logic unit 500 according to another embodiment of the present invention. Programmable logic unit 500 includes a 2-to-1 MUX 106M21 which is used to select one of the inputs LUTinA0 (511) and LUTinA1 (513) based on the input select signal 82. The output 502 of 106M21 is connected to the input of a 3-input look-up table LUT3. Two other inputs to LUT3 are LUTinB (515) and LUTinC (517). The output 504 of the programmable logic unit 500 is the output 504 from LUT3 which is selected from the output 502 of the 106M21, LUTinB (515) and LUTinC (517).

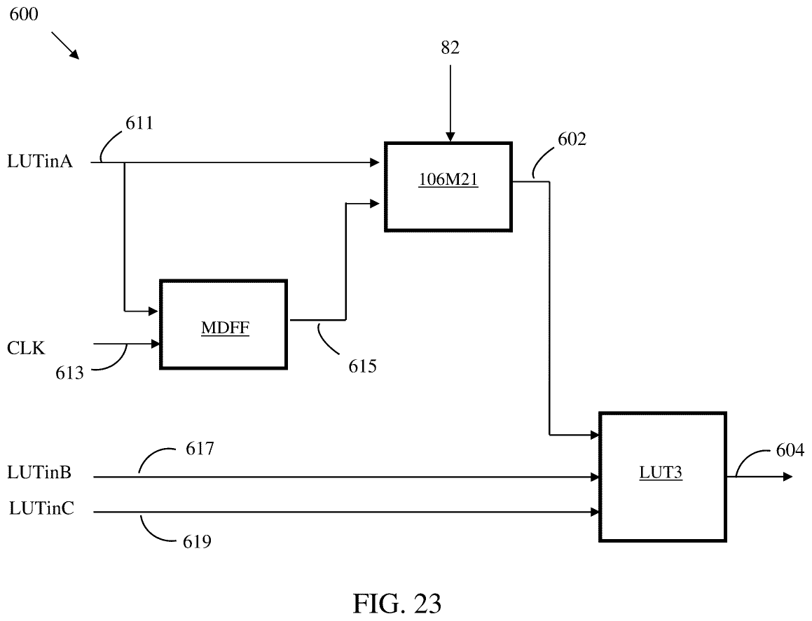

FIG. 23 illustrates a programmable logic unit 600 according to another embodiment of the present invention. Programmable logic unit 600 comprises an edge-triggered D-Flip Flop MDFF, a 2-to-1 MUX 106M21, and a 3-input look-up table LUT3. In this embodiment, an input signal LUTinA (611) is inputted to edge-triggered D-Flip Flop MDFF, as well as 2-to-1 MUX 106M21 having an input select signal 82. A clock signal 613 is also inputted to MDFF. The output 602 from 106M21 is selected from input 611 and the output 615 from MDFF, and is a first input to 3-input look-up table LUT3. Input signals LUTinB (617) and LUTinC (619) are second and third inputs to LUT3. The output 604 of the programmable logic unit 600 is the output from LUT3 which is selected from the output 602 of the 106M21, LUTinB (617) and LUTinC (619).

FIG. 24 illustrates a programmable logic unit 700 according to another embodiment of the present invention. Programmable logic unit 700 comprises an edge-triggered D-Flip Flop MDFF; two 2-to-1 MUX 106M21a, 106M2b with corresponding input select signals 82a and 82b; and a 3-input look-up table LUT3. In this embodiment, an input signal LUTinA (711) is inputted to an edge-triggered D-Flip Flop MDFF, as well as a 2-to-1 MUX 106M21a. A clock signal CLK 713 is also inputted to MDFF. The output 702 from 106M21a is selected from LUTinA 711 and the output 715 of MDFF and is a first input to look-up table LUT3. Input signals LUTinB0 (717) and LUTinB1 (719) are inputs to a second 2-to-1 MUX 106M21b. The output 704 from MUX 106M21b is a second input to LUT3. Input signal LUTinC (721) is a third input to LUT3. The output 706 of the programmable logic unit 700 is the output from LUT3 which is selected from the output 702 of the 106M21a, the output 704 of 106M21b and LUTinC (721).

FIG. 25 illustrates an example of a 4-input look-up table 102L4 according to an embodiment of the present invention. The 4-input look-up table 102L4 comprises sixteen memory elements 104a-p, 2-to-1 multiplexers 106M21 and inverters 150 connected between the second and third stages of multiplexers 106M21, as well as to the output of the fourth stage multiplexer 106M21. Four-input look-up table 102L4 may optionally further include additional inverters 150 between other stages of multiplexers, and/or pre-charge transistors 154 in a manner as previously described, for example, in the embodiments of FIGS. 5A, 5B and 6.

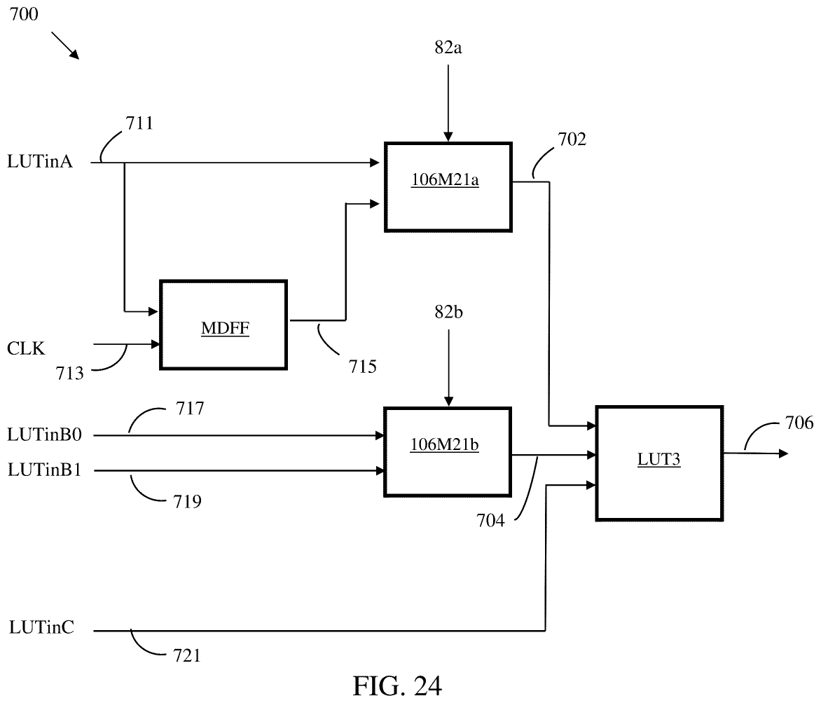

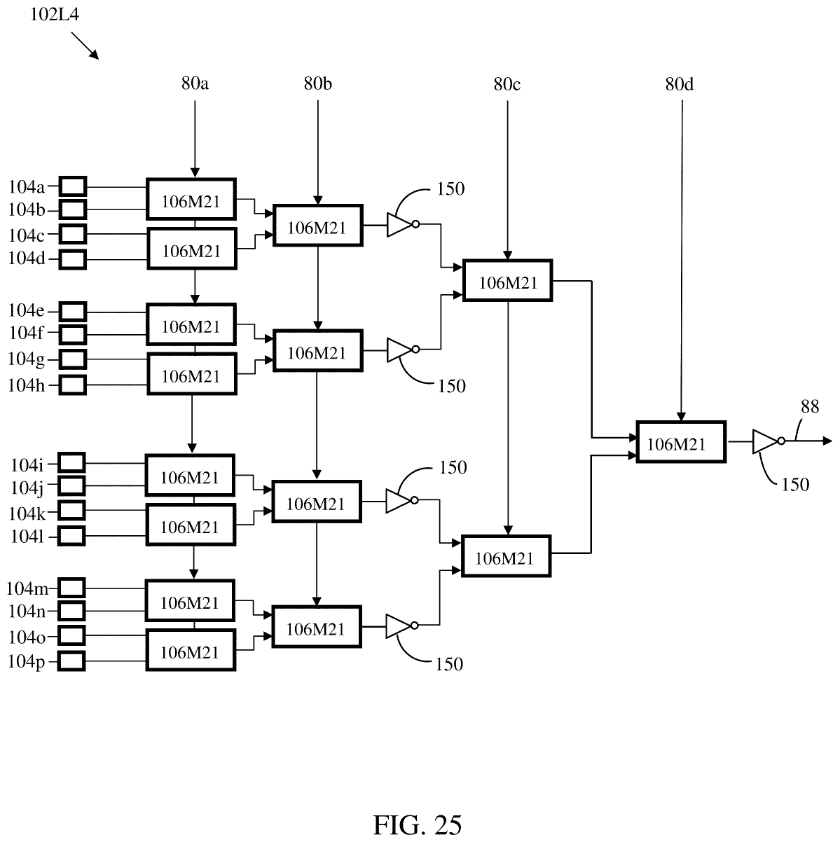

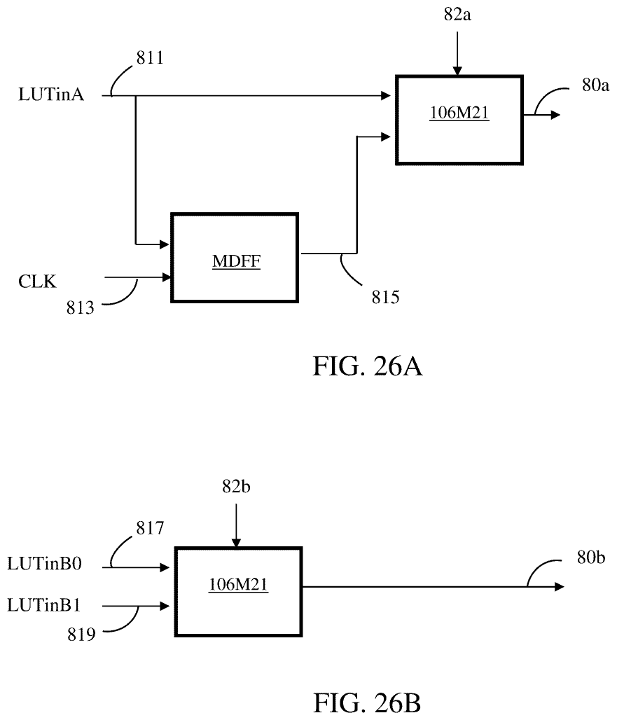

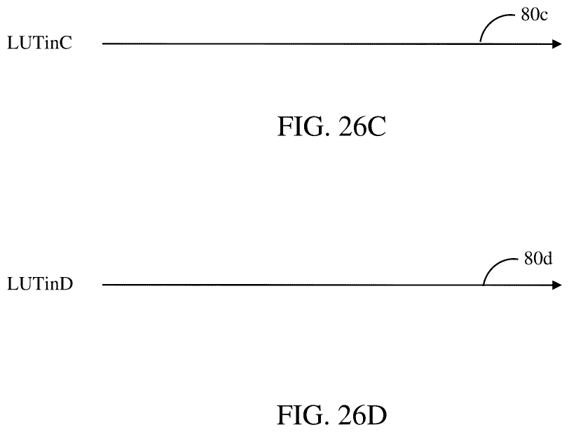

The inputs 80a-d to the 102L4 may originate from other programmable logic units. FIGS. 26A-26D illustrate non-limiting examples of sources from which inputs 80a-80d can be generated for the embodiment of FIG. 25. Of course, this is only one example and many other variations of sources for inputs 80a-80d could be substituted. In this example, input 80a is generated by a programmable logic unit wherein an input LUTinA (811) is inputted to an edge-triggered D-Flip Flop MDFF, as well as a 2-to-1 MUX 106M21 having an input select signal 82a. A clock signal 813 is also inputted to MDFF. The output 80a is the output from 106M21, which is selected from 811 and the output 815 from MDFF. Input 80b is generated by inputting input signals LUTinB0 (817) and LUTinB1 (819) to a 2-to-1 MUX 106M21. The output 80b is the output from 106M21, which is selected from one of LUTinB0 (817) and LUTinB1 (819) based on the input select signal 82b. The input 80c in this example is the direct input of LUTinC and the input 80d in this example is the direct input of LUTinD.

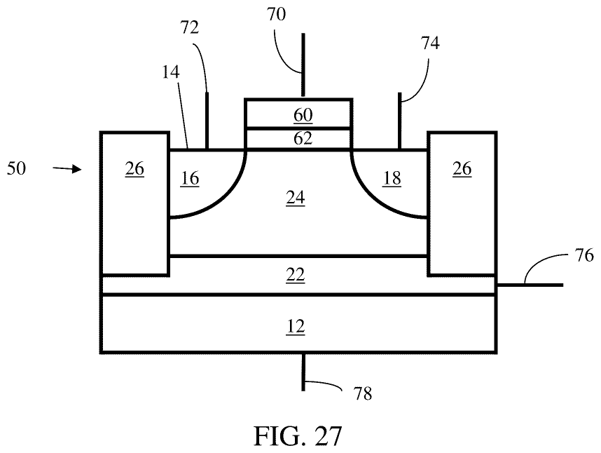

FIG. 27 is a schematic illustration of one non-limiting example of an SRAM memory cell 50 (single transistor bi-stable static random access memory bit cell) that can be used for the memory components 104 described herein. It is understood that the present invention is in no way limited to the use of memory cell 50 as memory component 104, as other types of memory cells could be alternatively used, including other types of SRAM cells, as well as any of the other types of memory cells that have been described above.

Cell 50 includes a substrate 12 of a first conductivity type, such as p-type conductivity type, for example. Substrate 12 is typically made of silicon, but may comprise germanium, silicon germanium, gallium arsenide, carbon nanotubes, or other semiconductor materials known in the art. The substrate 12 has a surface 14. A first region 16 having a second conductivity type, such as n-type, for example, is provided in substrate 12 and which is exposed at surface 14. A second region 18 having the second conductivity type is also provided in substrate 12, which is exposed at surface 14 and which is spaced apart from the first region 16. First and second regions 16 and 18 are formed by an implantation process formed on the material making up substrate 12, according to any of implantation processes known and typically used in the art. Alternatively, a solid state diffusion process can be used to form first and second regions 16 and 18.

A buried layer 22 of the second conductivity type is also provided in the substrate 12, buried in the substrate 12, as shown. Buried layer 22 may also be formed by an ion implantation process on the material of substrate 12. Alternatively, buried layer 22 can be grown epitaxially. A floating body region 24 of the substrate 12 having a first conductivity type, such as a p-type conductivity type, is bounded by surface, first and second regions 16,18, insulating layers 26 and buried layer 22. The floating body region 24 can be formed by an implantation process formed on the material making up substrate 12, or can be grown epitaxially. Insulating layers 26 (e.g., shallow trench isolation (STI)), may be made of silicon oxide, for example. Insulating layers 26 insulate cell 50 from neighboring cells 50 when multiple cells 50 are joined in an array to make a memory device. A gate 60 is positioned in between the regions 16 and 18, and above the surface 14. The gate 60 is insulated from surface 14 by an insulating layer 62. Insulating layer 62 may be made of silicon oxide and/or other dielectric materials, including high-K dielectric materials, such as, but not limited to, tantalum peroxide, titanium oxide, zirconium oxide, hafnium oxide, and/or aluminum oxide. The gate 60 may be made of polysilicon material or metal gate electrode, such as tungsten, tantalum, titanium and their nitrides.

Cell 50 further may further include word line (WL) terminal 70 electrically connected to gate 60, source line (SL) terminal 72 electrically connected to one of regions 16 and 18 (connected to 16 as shown, but could, alternatively, be connected to 18), bit line (BL) terminal 74 electrically connected to the other of regions 16 and 18 (connected to 18 as shown, but could, alternatively, be connected to 16 when 72 is connected to 18), and substrate terminal 78 electrically connected to substrate 12.

In another embodiment, the memory cell 50 has a n-type conductivity type as the first conductivity type and p-type conductivity type as the second conductivity type, as noted above.

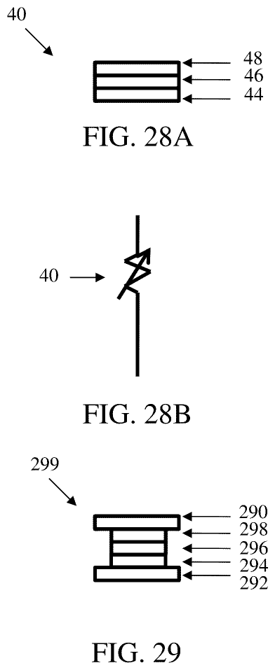

FIG. 28A schematically illustrates one non-limiting example of a resistance change element 40 that may be used in a programmable memory cell, resistance change element 40 being described for example in “ReRAM: History, Status, and Future”, Y. Chen, IEEE Transactions on Electron Devices, vol. 67, issue 4, April 2020, pp. 1420-1433, which is hereby incorporated herein, in its entirety, by reference thereto. As illustrated in FIG. 28B, a resistance change element 40 can be represented as a variable resistor, and may be formed from phase change memory material such as a chalcogenide or may take the form of metal-insulator-metal structure, in which transition metal oxide or perovskite metal oxide is used in conjunction with any reasonably good conductors. A resistance change element 40 may be formed from a top electrode 48, a bottom electrode 44, and a resistance change material 46. The conductive clement 42 may comprise tungsten or silicided silicon materials. Electrodes 44, 48 may be formed from one or more conductive materials, including, but not limited to titanium nitride, titanium aluminum nitride, or titanium silicon nitride. Resistance change material 46 is a material which properties, such as electrical resistance, can be modified using electrical signals. For the case of phase change memory elements, the resistivity depends on the crystalline phase of the material, while for the metal oxide materials, the resistivity typically depends on the presence or absence of conductive filaments. A crystalline phase of a phase change type resistive change material exhibits a low resistivity (e.g., ˜1 kΩ) state and an amorphous phase of that material exhibits a high resistivity state (e.g., >100 kΩ). Examples of phase change material include alloys containing elements from Column VI of the periodic table, such as GeSbTe alloys. Examples of metal-insulator-metal resistance change materials include a variety of oxides such as Nb₂O₅, Al₂O₃, Ta₂O₅, TiO₂, and NiO and perovskite metal oxides, such as SrZrO₃, (Pr,Ca)MnO₃ and SrTiO₃:Cr. Resistance change material 46 may also comprise ferroelectric and/or ferromagnetic materials.

FIG. 29 is a schematic illustration of one non-limiting example of a single magneto-resistive random-access memory (MRAM) bit cell 299, for example as described in “MRAM as Embedded Non-Volatile Memory Solution for 22FFL FinFET Technology”, O. Golonzka et. al, 18.1, 2018 IEEE International Electron Devices Meeting (IEDM), “Magnetoresistive Random Access Memory: Present and Future”, S. Ikegawa et. al., IEEE Transactions on Electron Devices, pp. 1407-1419, vol. 67, issue 4, April 2020, which are hereby incorporated therein, in their entireties, by reference thereto, that can be used for the memory components 104 described herein. It is understood that the present invention is in no way limited to the use of the memory cell shown in FIG. 29, as other types of memory cells could be alternatively used, including other types of single magneto-resistive random-access memory cells, as well as any of the other types of memory cells that have been described above. A MRAM bit cell 299 may comprise a top electrode 290, a bottom electrode 292, a fixed or reference layer 294, a free layer 298, and a tunnel barrier 296.

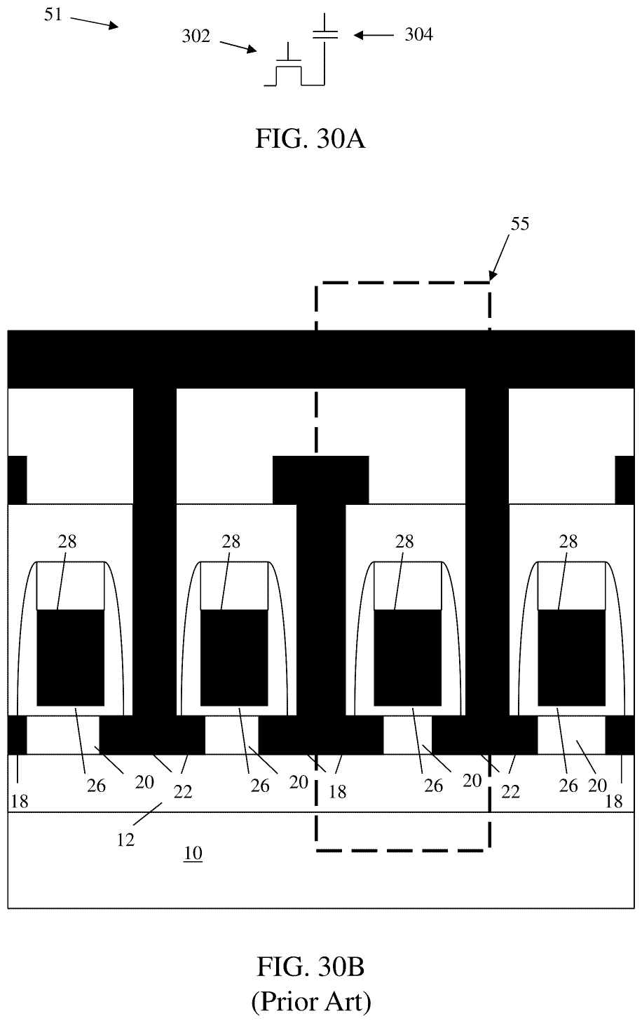

FIG. 30A is a schematic illustration of one non-limiting example of a single dynamic random-access memory bit cell 51 that can be used for the memory components 104 described herein and which is further described, for example in “1T-1C Dynamic Random Access Memory Status, Challenges, and Prospects”, A. Spessot and H. Oh, IEEE Transactions on Electron Devices vol. 67, issue 4, April 2020, pp. 1382-1393, which is incorporated herein, in its entirety, by reference thereto. Memory bit cell 51 comprises one select transistor 302 and one capacitor 304 (1T-1C). It is understood that the present invention is in no way limited to the use of memory cell 51 as memory component 104, as other types of memory cells could be alternatively used, including other types of DRAM cells, as well as any of the other types of memory cells that have been described above.

FIG. 30B illustrates another example of a single dynamic random-access memory bit cell 55 that can be used for the memory components 104 described herein. Memory bit cell 55 is based on the electrically floating body effect, which eliminates the capacitor used in the 1T-1C DRAM cells, and has been described, for example in “Semiconductor Memory Having Floating Body Transistor and Method of Operating”, “Scaled 1T-Bulk Devices Built with CMOS 90 nm Technology for Low-Cost eDRAM Applications”, Ranica et al., 2005 Symposium on VLSI Technology, Digest of Technical Papers (“Ranica”) and U.S. Pat. No. 6,937,516 “Semiconductor Device”, Fazan and Okhonin (“Fazan”), each of which are hereby incorporated herein, in their entireties, by reference thereto., which are incorporated herein, in their entireties, by reference thereto. Memory bit cell 55 may be fabricated in a bulk silicon substrate and on a silicon-on-insulator (SOI) substrate. The memory bit cell 55 illustrated in FIG. 30B is fabricated on silicon-on-insulator (SOI) substrate 10, and the memory states are represented by different levels of charge in the floating body 20. The floating body 20 is bounded by the buried oxide 12, the source and drain regions 18 and 22, respectively, and the gate dielectric 26. The gate dielectric 26 insulates the floating body 20 from the gate electrode 28.

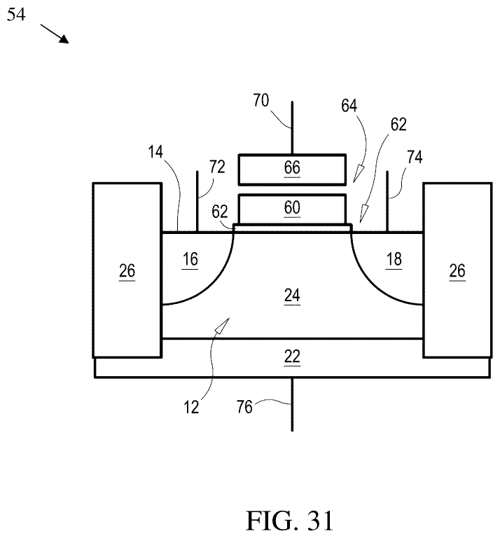

Memory components 104 may also comprise memory cells 54 (FIG. 31) having both volatile and non-volatile functionality, for example as described in U.S. Pat. No. 7,760,548, which is incorporated herein, in its entirety, by reference thereto. It is understood that the present invention is in no way limited to the use of memory cell 54 as memory component 104, as other types of memory cells could be alternatively used.

Cell 54 in FIG. 31 includes a substrate 12 of a first conductivity type, such as a p-type conductivity type, for example. Substrate 12 is typically made of silicon, but may comprise germanium, silicon germanium, gallium arsenide, carbon nanotubes, or other semiconductor materials known in the art. The substrate 12 has a surface 14. A first region 16 having a second conductivity type, such as n-type, for example, is provided in substrate 12 and which is exposed at surface 14. A second region 18 having the second conductivity type is also provided in substrate 12, which is exposed at surface 14 and which is spaced apart from the first region 16. First and second regions 16 and 18 are formed by an implantation process formed on the material making up substrate 12, according to any of implantation processes known and typically used in the art.

A buried layer 22 of the second conductivity type is also provided in the substrate 12, buried in the substrate 12, as shown. Region 22 is also formed by an ion implantation process on the material of substrate 12. A body region 24 of the substrate 12 is bounded by surface 14, first and second regions 16,18 and insulating layers 26 (e.g., shallow trench isolation (STI)), which may be made of silicon oxide, for example. Insulating layers 26 insulate cell 50 from neighboring cells 50 when multiple cells 50 are joined to make a memory device. A floating gate or trapping layer 60 is positioned in between the regions 16 and 18, and above the surface 14. Trapping layer/floating gate 60 is insulated from surface 14 by an insulating layer 62. Insulating layer 62 may be made of silicon oxide and/or other dielectric materials, including high-K dielectric materials, such as, but not limited to, tantalum peroxide, titanium oxide, zirconium oxide, hafnium oxide, and/or aluminum oxide. Floating gate/trapping layer 60 may be made of polysilicon material. If a trapping layer is chosen, the trapping layer may be made from silicon nitride or silicon nanocrystal, etc. Whether a floating gate 60 or a trapping layer 60 is used, the function is the same, in that they hold data in the absence of power. The primary difference between the floating gate 60 and the trapping layer 60 is that the floating gate 60 is a conductor, while the trapping layer 60 is an insulator layer. Thus, typically one or the other of trapping layer 60 and floating gate 60 are employed in device 50, but not both.

A control gate 66 is positioned above floating gate/trapping layer 60 and insulated therefrom by insulating layer 64 such that floating gate/trapping layer 60 is positioned between insulating layer 62 and surface 14 underlying floating gate/trapping layer 60, and insulating layer 64 and control gate 66 positioned above floating gate/trapping layer 60, as shown. Control gate 66 is capacitively coupled to floating gate/trapping layer 60. Control gate 66 is typically made of polysilicon material or metal gate electrode, such as tungsten, tantalum, titanium and their nitrides. The relationship between the floating gate/trapping layer 60 and control gate 66 is similar to that of a nonvolatile stacked gate floating gate/trapping layer memory cell. The floating gate/trapping layer 60 functions to store non-volatile memory data and the control gate 66 is used for memory cell selection.

Cell 54 includes four terminals: word line (WL) terminal 70, source line (SL) terminal 72, bit line (BL) terminal 74 and buried well (BW) terminal 76. Terminal 70 is connected to control gate 66. Terminal 72 is connected to first region 16 and terminal 74 is connected to second region 18. Alternatively, terminal 72 can be connected to second region 18 and terminal 74 can be connected to first region 16. Terminal 76 is connected to buried layer 22.

When power is applied to cell 54, cell 54 operates like a currently available capacitorless DRAM cell. In a capacitorless DRAM device, the memory information (i.e., data that is stored in memory) is stored as charge in the floating body of the transistor, i.e., in the body 24 of cell 50. The presence of the electrical charge in the floating body 24 modulates the threshold voltage of the cell 50, which determines the state of the cell 50.

Memory component 104 may also comprise memory cells 52 having both volatile and non-volatile functionality, where resistive change memory clement is used to store non-volatile memory data, such as described for example in U.S. Pat. No. 9,025,358. U.S. Pat. No. 9,025,358 is hereby incorporated herein, in its entirety, by reference thereto. It is understood that the present invention is in no way limited to the use of memory cell 52 as memory component 104, as other types of memory cells could be alternatively used. Also, different types of resistance change elements from those disclosed could be substituted.

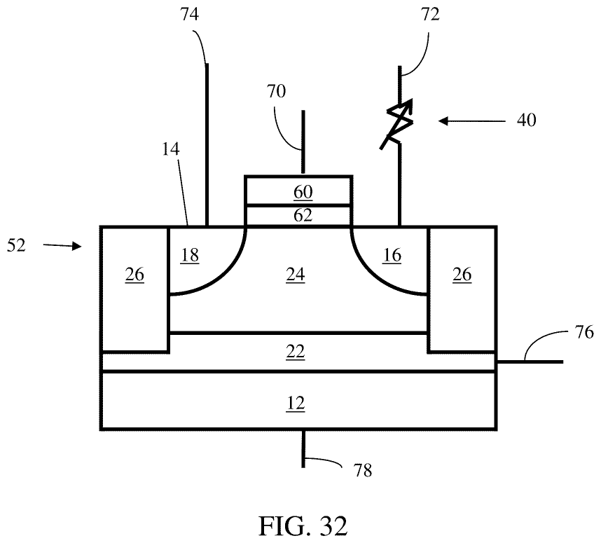

Cell 52 (FIG. 32) is formed in and/or on a substrate 12 of a first conductivity type, such as a p-type conductivity type, for example. Substrate 12 may include any suitable substrate, illustrative, non-exclusive examples of which include silicon, germanium, silicon germanium, gallium arsenide, carbon nanotubes, and/or other semiconductor materials.

Substrate 12 has a surface 14 and includes a buried layer 22 of a second conductivity type, such as n-type conductivity type. Buried layer region 22 may be formed using any suitable process and/or method performed on the material of substrate 12, illustrative, non-exclusive examples of which include ion implantation process and/or epitaxial growth.

Memory cell 52 includes a first region 16 having a second conductivity type, such as n-type conductivity type, that is formed in substrate 12, and a second region 18 having a second conductivity type, that is formed in substrate 12 and spaced apart from the first region 16. First and second regions 16 and 18, respectively, are exposed at surface 14 and may be formed using any suitable method and/or process, illustrative, non-exclusive examples of which include ion implantation, solid state diffusion, and/or epitaxial growth.

A floating body region 24 of the substrate 12 having a first conductivity type, such as p-type conductivity type, is bounded by surface 14, first and second regions 16 and 18, buried layer 22, and insulating layer 26. The floating body region 24 may be formed using any suitable method and/or process such as ion implantation, solid state diffusion, and/or epitaxial growth. Insulating layer 26 may be formed from any suitable insulating and/or dielectric materials, illustrative, one non-exclusive example of which includes silicon dioxide. Insulating layers 26 may insulate cell 50 from neighboring cells 50 when multiple cells 50 are joined in an array to form a memory device.

A gate 60 may be positioned in between regions 16 and 18, and above the surface 14. Gate 60 is insulated from surface 14 by an insulating layer 62. Insulating layer 62 may be formed from any suitable dielectric material, illustrative, non-exclusive examples of which include silicon oxide, high-K dielectric materials, tantalum peroxide, titanium oxide, zirconium oxide, hafnium oxide, and/or aluminum oxide. Gate 60 may be made from any suitable conductive material, illustrative, non-exclusive examples of which include a polysilicon material, a metal gate electrode, tungsten, tantalum, titanium and/or their nitrides.

A resistive change memory element 40 is positioned above one of the regions having second conductivity type. The resistive change memory element is shown as a variable resistor in FIG. 32, and may be formed by bipolar resistive memory element, such as transition metal oxides, ferroelectric, and/or ferromagnetic materials. However, other types of resistive change element may be substituted, including, but not limited to an electrode and a bipolar resistive change material, or phase change memory material such as a chalcogenide or conductive bridging memory or metal oxide memory, as described, for example in U.S. Pat. No. 8,194,451 and may take the form of metal-insulator-metal structure, in which transition metal oxide or perovskite metal oxide is used in conjunction with any reasonably good conductors. U. S. Pat. No. 8, 194,451 is hereby incorporated herein, in its entirety, by reference thereto.

The resistivity state of a bipolar resistive memory element depends on the polarity of the potential difference or current flow across the bipolar resistive memory element. The resistive change memory element 40 is shown to be electrically connected to the source line region 16 in FIG. 32. Alternatively, resistive change memory element 40 may be connected to the bit line region 18. The resistive change memory element 40 is electrically connected to the floating body transistor which comprises the first region 16, the floating body region 24, the second region 18, and the gate electrode 60, the separation distance between the volatile memory (i.e. the floating body transistor) and the non-volatile memory (i.e. the resistive change memory element 40) can be small, for example from about 90 nm to about 1 μm, preferably from about 90 nm to about 500 nm, more preferably from about 90 nm to about 100 nm if the resistive change element 40 is located between the surface 14 and the bottom-most (or first) metal layer for a 28-nm technology, or less than 1 μm if the resistive change element 40 is located below the fourth metal layer for a 28-nm technology process, or less than 10 μm, depending on for example which metal layer the addressable line (e.g. source line 72) is implemented at as well as the process technology node. Cell 50 further includes a word line (WL) terminal 70 electrically connected to gate 60, a source line (SL) terminal 72 electrically connected to region 16, a bit line (BL) terminal 74 electrically connected to region 18, a buried well (BW) terminal 76 electrically connected to buried layer region 22, and a substrate terminal 78 electrically connected to substrate 12. Alternatively, the SL terminal 72 may be electrically connected to region 18 and BL terminal 74 may be electrically connected to region 16.

As discussed in more detail herein, the conductivity types described above are exemplary conductivity types and other conductivity types and/or relative conductivity types are also within the scope of the present disclosure. As an illustrative, non-exclusive example, memory cell 52 may have and/or include a p-type conductivity type as the first conductivity type and n-type conductivity type as the second conductivity type.

From the foregoing it can be seen that a reconfigurable logic device and architecture has been described. Examples of other programmable logic devices configured using the reconfigurable fabric such as look-up Tables, D-Flip Flops, and multiplexers have also been described. While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiments, methods, and examples, but by all embodiments and methods within the scope and spirit of the invention as claimed.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

1. A look-up-table comprising:
a plurality of programmable memory cells; and
a plurality of multiplexers connected in multiple stages to form a tree-like structure,
wherein a first stage of said multiple stages is connected to said plurality of programmable memory cells and has a greatest number of said multiplexers of all of said multiple stages;
wherein a last stage of said multiple stages has a least number of said multiplexers and is configured to forward a look-up table output that is a selected memory state of one of said plurality of memory cells;
wherein each of said plurality of multiplexers comprises at least two transistors; and
at least one inverter connected to an output of at least one of said plurality of multiplexers;
and input select pins of said plurality of multiplexers configured to connect to input sources to provide input to said look-up-table.

2. The look-up table of claim 1, comprising a plurality of said inverters,
wherein outputs of every stage of said multiple stages are connected to inputs of said inverters; and outputs of said inverters are connected to inputs of a subsequent stage of multiplexers, except for one inverters connected to said multiplexer in said last stage;.

3. The look-up table of claim 1, wherein inputs provided to said input select pins are all independent of one another.

4. The look-up table of claim 1, further comprising buffers between at least two stages of said multiple stages of multiplexers.

5. The look-up table of claim 4, wherein said buffers comprise additional ones of said inverters.

6. The look-up table of claim 1, wherein at least one of said plurality of programmable memory cells comprises a static random access memory bit cell.

7. The look-up table of claim 1, wherein at least one of said plurality of programmable memory cells comprises a single transistor bi-stable static random access memory bit cell.

8. The look-up table of claim 1, wherein at least one of said plurality of programmable memory cells comprises a resistance change element.

9. The look-up table of claim 1, wherein at least one of said plurality of programmable memory cells comprises a single magneto-resistive random-access memory bit cell.

10. The look-up table of claim 1, wherein at least one of said plurality of programmable memory cells comprises a phase change material.

11. The look-up-table of claim 1, wherein at least one of said plurality of programmable memory cells comprises a metal-oxide-metal system.

12. The look-up table of claim 1, wherein at least one of said plurality of programmable memory cells comprises a single dynamic random-access memory bit cell.

13. The look-up table of claim 1, wherein said look-up table output is pre-charged to a predetermined state before forwarding the selected memory cell state.

14. The look-up table of claim 13, further comprising a transistor to set said look-up table output to said predetermined state.

15. The look-up table of claim 1, wherein the look-up table output is configured to write the state of the programmable memory cell.

16. The look-up table of claim 1, further comprising a control circuitry to enable write to the programmable memory cells.

17. The look-up table of claim 1, wherein said plurality of multiplexers comprise two-input to one-output multiplexers and said tree-like structure is a binary tree arrangement, said plurality of multiplexers being arranged and configured to forward one said selected memory state;
wherein each said multiplexer comprises one p-channel metal-oxide-semiconductor field-effect transistor and one n-channel metal-oxide-semiconductor field-effect transistor; and
wherein said look-up table comprises look-up table input pins, each of said look-up-table input pins being connected to said select input signals of said multiplexers in each said stage.

18. The look-up table of claim 1, wherein each of said multiplexers comprises one or more memory cells with state outputs that are used to multiplex two or more look-up-table inputs; each output of said memory cells with state is connected to a select input signal of one of said multiplexers in one of the levels of said tree-like structure.

19. The look-up table of claim 18, wherein said multiplexers are two-input to one-output multiplexers, each said multiplexer comprising one p-channel metal-oxide-semiconductor field-effect transistor and one n-channel metal-oxide-semiconductor field-effect transistor; and
wherein one of said state outputs is connected to one of a gate of said p-channel transistor and a gate of said n-channel transistor to forward one of two inputs.

20. A two-input to one-output programmable switch module comprising:
one p-channel metal-oxide-semiconductor field-effect transistor having a gate pin; and
one n-channel metal-oxide-semiconductor field-effect transistor connected to said gate pin;
wherein a state of a programmable memory cell is connected to said gate pin; and
said switch module is configured to select one of two inputs.

21. The switch module of claim 20, wherein said programmable memory cell comprises a static random access memory bit cell.

22. The switch module of claim 20, wherein said programmable memory cell comprises a single transistor bi-stable static random access memory bit cell.

23. The switch module of claim 20, wherein said programmable memory cell comprises a resistance change element.

24. The switch module of claim 20, wherein said programmable memory cell comprises a single magneto-resistive random-access memory bit cell.

25. The switch module of claim 20, wherein said programmable memory cell comprises a phase change material.

26. The switch module of claim 20, wherein said programmable memory cell comprises a metal-oxide-metal system.

27. The switch module of claim 20, wherein said programmable memory cell comprises a single dynamic random-access memory bit cell.

28. An edge triggered D-flip flop comprising:
a D-flip flop input;
first and second multiplexers that are cascaded one after another, said first multiplexer comprising multiple first inputs and a first output, said second multiplexer comprising multiple second inputs and a second output;
wherein said D-flip flop input is connected to one of said first inputs, said first output is fed back to another of said first inputs and said first output is also connected to one of said second inputs; and
wherein said second output is fed back to another of said second inputs, and said second output is an output of the D-flip flop.

29. An edge triggered D-flip flop comprising:
a D-flip flop input and a D-flip flop output;
first and second multiplexers that are cascaded one after another, said first multiplexer comprising multiple first inputs and a first output, said second multiplexer comprising multiple second inputs and a second output;
first and second capacitors;
a first inverter having a first inverter input and a first inverter output; and
a second inverter having a second inverter input and a second inverter output;
wherein said D-flip flop input is connected to one of said first inputs, said first output is fed back to another of said first inputs and said first output is also connected to said first capacitor and said first inverter input;
wherein said first inverter output is connected to one of said second inputs, said second output is fed back to another of said second inputs and said second output is also connected to said second capacitor and said second inverter input; and
wherein said second output is also connected to said D-flip flop output.

30. A level triggered D-flip flop comprising:
a first 2-input look-up table having two first inputs and a first output;
a second 2-input look-up table having two second inputs and a second output;
a third 2-input look-up table having two third inputs and a third output;
a fourth 2-input look-up table having two fourth inputs and a fourth output;
a D-flip flop input connected to one of said first inputs and one of said second inputs;
a clock input connected to another of said first inputs and another of said second inputs;
said first output connected to one of said third inputs;
said second output connected to one of said fourth inputs;
said third output connected to another of said fourth inputs and a first output of said level triggered D-flip flop; and
said fourth output connected to another of said third inputs and a second output of said level triggered D-flip flop.

31. A level triggered D-flip flop comprising:
a first look-up-table having three or more first inputs and a first output;
a second look-up table having three or more second inputs and a second output;
a D-flip flop input connected to one of said first inputs and one of said second inputs;
a clock input connected to another of said first inputs and another of said second inputs;
said first output connected to still another of said second inputs and a first output of said level triggered D-flip flop; and
said second output connected to still another of said first inputs and a second output of said level triggered D-flip flop.

32. An edge triggered D-flip flop comprising:
a first look-up-table based level triggered D-flip flop module having at least two first inputs and a first output;
a second look-up-table based level triggered D-flip flop module having at least two second inputs and a second output;
a D-flip flop input connected to one of said first inputs;
a clock input connected to another of said first inputs and one of said second inputs;
said first output connected to another of said second inputs; and
said second output being an output of said edge triggered D-flip flop.

33. An edge triggered D-flip flop comprising:
a first look-up-table with three or more first inputs and a first output;
a second look-up table with three or more second inputs and a second output, said first and second look-up tables being connected to enable D-flip-flop function;
a D-flip flop input connected to one of said first inputs;
a D-flip flop triggering input connected to another of said first inputs and one of said second inputs;
said first output being fed back to still another of said first inputs and inputted to another of said second inputs; and
said second output being fed back to still another of said second inputs and outputted as a D-flip flop output.
